(19) United States
(12) Patent Application Publication
(10) Pub. No.: US 2019/0100855 A1
(43) Pub. Date: Apr. 4, 2019

(54) ELECTROCHEMICAL METHOD AND APPARATUS FOR CONSUMING GASES

(71) Applicant: Atomospherix, LLC, Beachwood, OH (US)

(72) Inventor: Daniel Scherson, Beachwood, OH (US)

(21) Appl. No.: 16/086,358

(22) PCT Filed: Mar. 21, 2017
(86) PCT No.: PCT/US2017/023287

§ 371 Date: Sep. 19, 2018

Related U.S. Application Data
(60) Provisional application No. 62/310,941, filed on Mar. 21, 2016.

(51) Int. Cl. C25D 21/04; H01L 51/52

(52) U.S. Cl. CPC C25D 21/04; E06B 3/677; H01L 51/5259

(57) ABSTRACT

An apparatus for consuming gases includes an electrochemical cell comprising a cathode, an anode, and an electrolyte. The cell is operable to produce an electrochemical reaction that forms on the cathode a reactive material comprising at least one of a metal, an alloy, and an intercalation compound. The cell is constructed so that the reactive material formed on the cathode is exposed to the gases that are to be consumed.

### TECHNICAL FIELD

The invention relates generally to gas consuming devices and products. More particularly, the invention relates to a system, method, and apparatus for consuming gases.

### BACKGROUND OF THE INVENTION

There are many scenarios in which it may be desirable to consume gases to remove them from an environment. For instance, one may wish to consume gases in a sealed enclosure in order to maintain a desired pressure, such as a vacuum, in the enclosure. As another example, it may be desirable to consume gases in an environment, such as an enclosure, where the presence of those gases is undesirable. For instance, it may be desirable to remove air, oxygen, nitrogen, carbon dioxide, water (e.g., water vapor), or a combination of these gases.

### SUMMARY OF THE INVENTION

The present invention relates to a system, method, and apparatus for consuming gases through an electrochemical reaction that produces materials that react with those gases to consume them.

According to one aspect, an apparatus for consuming gases through an electrochemical reaction includes an electrochemical cell comprising a cathode and an anode supported on a non-volatile solid electrolyte. The solid electrolyte is a non-volatile, Li-ion conducting electrolyte. The cathode is constructed of one or more materials onto which metallic Li can be electrodeposited or which are known to form alloys with metallic Li. The anode is constructed of a lithium-ion containing material, such as a lithium ion intercalation material, whereby lithium ions can be inserted into or released from a host lattice, such as a layered material. The cell is operable to deposit metallic lithium on the cathode, which is exposed to the environment in which gases are to be consumed.

According to another aspect, the cathode can be constructed of at least one of nickel, copper, silicon, and tin. Other materials could also be used.

According to another aspect, the solid electrolyte can include a solid polymer electrolyte (“SPE”) or a ceramic type ion conducting electrolyte such as lithium phosphorous oxynitride, (“LiPON”), LISICON and thio-LISICON, (LiₓM_{1-y}M′_{y}S₄; where M=Si, Ge and M′=P, Al, Zn, Ga, Sb).

According to another aspect, the SPE can include a lithium hexafluorophosphate (LiPF₆) solution in polyethylene oxide (“PEO”) or lithium bis(trifluoromethane)sulfonamide (CF₃SO₂NLiSO₂CF₃) in polyphosphazene.

According to another aspect, the anode can be constructed of a lithium alloy that preferably should not be exposed to the gas in the enclosure.

According to another aspect, the solid electrolyte can have a thin, flat, and elongated planar configuration, wherein the cathode and anode are deposited on in an interdigitated configuration.

According to another aspect, the electrochemical cell can have a construction capable of conforming to the shape of a portion of the enclosure.

According to another aspect, the apparatus includes a source of power, such as a battery, for powering the cell, and/or a heating element for heating the cell.

According to another aspect, the cathode can be constructed of a material that does not form alloys with lithium, such as copper or nickel, wherein the electrochemical cell when actuated deposits lithium metal from the solid electrolyte onto the cathode while the anode releases lithium ions into the solid electrolyte.

According to another aspect, the gases within the enclosure can permeate the solid electrolyte and react with the lithium metal on the cathode.

According to another aspect, the cathode is porous in order to permit gases to reach and react with the lithium metal on the cathode.

According to another aspect, the cathode can be constructed of a material that forms alloys with lithium, such as silicon and tin, wherein the cell is operable to cause such lithium alloys to form, causing the cathode to rupture and expose the lithium alloy to the gases in the enclosure.

According to another aspect, the cathode can be constructed of a material that forms alloys with lithium, such as silicon and tin, wherein the cell is operable to cause the cathode to rupture and expose the lithium alloy to the gases in the enclosure.

According to another aspect, the solid electrolyte can be a solid polymer electrolyte (“SPE”) including a Li-ion non-volatile electrolyte containing a dissolved metal salt.

According to another aspect, the anode can be constructed of a lithiated transition metal oxide, such as lithium cobalt oxide (LiCoO₂) and lithium titanate (LTO), which are examples of lithium-ion intercalation materials.

According to another aspect, the cathode can be constructed of a conducting material such as copper or nickel serving as a current collector coated with a layer of silicon or tin.

According to another aspect, the apparatus can include actuator including sensors and electronics or circuitry that is adapted to activate the apparatus remotely from outside the enclosure.

According to another aspect, the actuator can be adapted to monitor pressure in the enclosure and activate/deactivate the apparatus in response to pressure in the enclosure.

According to another aspect, the actuator can be adapted for non-electronic manual or mechanical activation, which can include at least one of a rupturable member that, when destroyed, actuates the electronics or circuitry; a removable member that, when removed manually, actuates the electronics or circuitry; and a mechanism that is actuated magnetically to actuate the electronics or circuitry.

According to another aspect, the actuator can include at least one of RF transducers, tags, interrogators, and receivers adapted to provide information regarding the apparatus and actuate the apparatus in response to an RF signal applied externally to the enclosure via a controller.

According to another aspect, the actuator can include sealed electrical feedthroughs in the walls of the enclosure that provide for wired connections to the apparatus from outside the enclosure.

According to another aspect, the actuator can include a wireless inductive charging power supply.

According to another aspect, a method for consuming gases in an enclosure can include providing an electrochemical cell with a cathode exposed to the gases in the enclosure, and activating the electrochemical cell to cause electrodeposition of a reactive metal on the cathode. Reactive metal on the cathode reacts with the gases in the enclosure to consume the gases.

According to another aspect, the step of providing an electrochemical cell can include providing a solid electrolyte; providing a cathode on the solid electrolyte, the cathode comprising a material with which lithium does not form alloys, such as nickel or copper; and providing an anode on the solid electrolyte. The anode can include a lithium-ion containing material, such as a lithium alloy or a lithiated transition metal oxide.

According to another aspect, a method for consuming gases in an enclosure can include operating an electrochemical cell to electrodeposit lithium onto an electrode (cathode); and reacting the lithium with the gases in the enclosure to consume those gases and thereby consume the gases in the enclosure.

According to another aspect, a method for consuming gases in an enclosure can include providing an electrochemical cell with a cathode exposed to the gases in the enclosure; and activating the electrochemical cell to cause incorporation of a reactive metal into the cathode of the electrochemical cell. The incorporation of the reactive metal in the cathode causes the cathode to crack or fissure, which exposes the metal to the gases in the enclosure. The metal alloy reacts with and consumes the gases.

According to another aspect, a method for consuming gases in an enclosure can include operating an electrochemical cell to form lithium alloys on a cathode; and reacting the lithium alloy with the gases in the enclosure to consume those gases. Lithium alloys such as such as those formed between lithium and silicon and between lithium and tin will undergo spontaneous cracking as the Li is inserted into Si and Sn due to the volume expansion associated with the formation of the lithium alloy. This process will lead to further exposure of the alloy to gases in the sealed enclosure.

According to another aspect, an apparatus for consuming gases includes an electrochemical cell comprising a cathode, an anode, and an electrolyte, wherein the cell is operable to produce an electrochemical reaction that forms on the cathode a reactive material comprising at least one of a metal, an alloy, and an intercalation compound, and wherein the cell is constructed so that the reactive material formed on the cathode is exposed to the gases that are to be consumed.

According to another aspect, the reactive metal can be lithium, and: the anode can be is constructed of a lithium-ion containing material; the electrolyte can include a non-volatile lithium ion conducting material; and the cathode can be constructed of a material with which lithium can form alloys, upon which metallic lithium can be deposited, or with which lithium can form an intercalation compound.

According to another aspect, the electrolyte can include a lithium containing salt selected from the following group:

lithium hexafluorophosphate (LiPF₆);

lithium bis(trifluoromethane)sulfonamide (CF₃SO₂NLiSO₂CF₃);

lithium trifluoromethanesulfonate (CF₃SO₃Li);

lithium tetrafluoroborate (LiBF₄);

lithium perchlorate (LiClO₄);

lithium bromide (LiBr).

According to another aspect, the electrolyte can include a solid polymer electrolyte. The solid polymer electrolyte can include the lithium containing salt in solution with polyethylene oxide.

According to another aspect, the cathode can be constructed of at least one of nickel, copper, silicon, and tin.

According to another aspect, the anode can be constructed of a lithium-ion containing material, such as a lithium alloy or a lithiated transition metal oxide such as lithium cobalt oxide (LiCoO₂) and lithium titanium oxide (LTO).

According to another aspect, the apparatus can include a source of power, such as a battery, for powering the cell. The apparatus can also include a heater for heating the cell.

According to another aspect, the cell can have a multilayer configuration in which the cathode comprises a cathode layer, the anode comprises an anode layer, and the electrolyte comprises an electrolyte layer. The cathode layer, anode layer, and electrolyte layer can together form the electrochemical cell as a multilayer thin film cell. The multilayer configuration can include multiple cathode layers, multiple anode layers, and multiple electrolyte layers are arranged in an alternating fashion.

According to another aspect, the anode layer can include a film substrate upon which a layer of anode material is disposed. The cathode layer can include a lithium ion conducting film that supports one or more conductors formed of a metal with which lithium can form alloys, upon which metallic lithium can be deposited, or with which lithium can form an intercalation compound. The cathode layer can include a lithium ion conducting film that supports one or more conductors formed of a material with which lithium forms alloys. The electrolyte layer can include a thin film solid polymer electrolyte. The electrolyte layer can include a thin film ceramic type ion conducting electrolyte such as LiPON, LISICON and thio-LISICON.

According to another aspect, the cathode layer and electrolyte layer can be formed as a unitary sheet in which the electrode layer can include a lithium ion conducting film and the cathode can include one or more conductors of a metal upon which metallic lithium can be deposited or with which lithium can form alloys, such as thin wires or traces, that is deposited on the lithium ion conducting film.

According to another aspect, the cathode can be constructed as a mesh.

According to another aspect, upon activation of the cell, lithium ions will be released from the anode layer into the electrolyte layer, and metallic lithium from the one or more electrolyte layers will be deposited on or alloy with the conductors of the cathode layer.

According to another aspect, the multilayer cell can form one of a plurality of layers in a multilayer panel that includes one or more layers of material in addition to the multilayer cell. The multilayer cell and the layers in addition to the multilayer cell can be combined to form the multilayer panel through at least one of lamination, edge sealing, and mechanical connections. The multilayer cell can be operative to consume water vapor within the multilayer panel. The multilayer panel can include an OLED display panel.

According to another aspect, the electrochemical cell when operated within an enclosure can be used to consume gases within the enclosure. The apparatus can be used to form or maintain a vacuum by consuming gases within a sealed enclosure. The enclosure can include a thermal insulation vacuum panel.

According to another aspect, the multilayer cell can be applied to one or more surfaces within an enclosure. The enclosure can include a thermal insulation vacuum panel. The multilayer cell can be applied on an inner surface of one or more gas impermeable membrane panels that surround a porous core material. The multilayer cell can conform to the shape of a portion of the enclosure.

According to another aspect, the apparatus can be configured for integration into an argon filled insulated window to expose the reactive material formed on the cathode to the argon filled space between panes of the window. The reactive material formed on the cathode can react with non-noble gases that may enter the argon filled space. The electrochemical cell can be integrated into structure of the insulated window, such as the window frame or a spacer used to maintain the spaced relationship of the window panes.

According to another aspect, the apparatus can also include a power source for supplying power for operating the electrochemical cell and actuator for controlling the supply of power to the electrochemical cell. The electrochemical cell, power source, and actuator can have a unitary construction. The actuator can include electronics or circuitry that is adapted to autonomously sense conditions and control operation of the electrochemical cell in response to the sensed conditions. The actuator can include components adapted to activate the apparatus remotely from outside the enclosure, such as RF transducers, tags, interrogators, transmitters, receivers. The actuator can include a non-electronic manual or mechanical activator, such as a rupturable member that, when destroyed, actuates the electronics or circuitry. The actuator can also include a removable member that, when removed manually, actuates the electronics or circuitry. The actuator can also include a mechanism that is actuated magnetically to actuate the electronics or circuitry.

### BRIEF DESCRIPTION OF THE DRAWINGS

The foregoing and other features of the invention will become apparent to those skilled in the art to which the invention relates upon reading the following description with reference to the accompanying drawings, in which:

FIG. 1 illustrates a system for consuming gases.

FIG. 2 illustrates a portion of the system of FIG. 1.

FIG. 3 illustrates portion of the system indicated generally at III-III in FIG. 2, according a first embodiment of the invention.

FIGS. 4-6 illustrate processes performed by the system in accordance with the first embodiment.

FIG. 7 illustrates portion of the system indicated generally at VII-VII in FIG. 2, according to a second embodiment of the invention.

FIGS. 8-9 illustrate processes performed by the system in accordance with the second embodiment.

FIG. 10 illustrates a portion of the system of FIG. 1, according to another embodiment.

FIGS. 11-14 illustrate different constructions and implementations of the system of FIG. 1.

FIG. 15 illustrates an example construction that can be used to produce a portion of the system.

### DESCRIPTION

The invention relates generally to consuming gases. More particularly, the invention relates to a system, method, and apparatus for consuming gases through an electrochemical reaction that produces materials that react with and thereby consume the gases.

According to the invention, a system 10 includes an apparatus 20 for consuming gases. The apparatus 20 can, for example, be used to consume gases in environment, such as an enclosure 12. The term “enclosure” as used herein is meant to encompass any structure that defines or helps define a space or confinement in which the consumption of gases may be desired. The enclosure 12, and the confinement defined by the enclosure, does not necessarily have to be sealed from the surrounding environment. To the contrary, the enclosure 12 and, thus, the confinement, can be as open to the surrounding environment as the particular application for which the apparatus 20 is employed dictates or allows.

The enclosure 12 can be sealed to the extent for which the particular application dictates. For example, if the application is one in which ingress of gases external to the enclosure and egress of gases internal to the enclosure is not wanted, then the enclosure 12 must be constructed using materials and seals capable of preventing such ingress and egress. If the application is one in which some ingress/egress of gases is permissible or expected, then the enclosure can be constructed accordingly. In this manner, the enclosure 12 could include some degree of openness to permit or even promote some venting to outside environments.

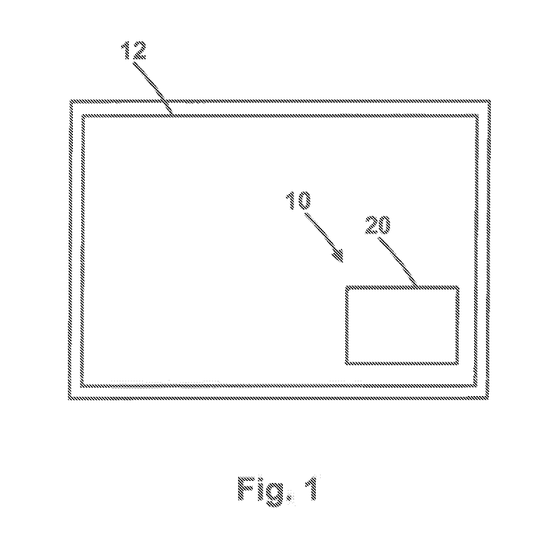

The enclosure 12 can have any application dependent size, shape, or construction, the enclosure 12 is represented schematically in FIG. 1. Additionally, the enclosure 12 can be constructed of any desired material as long as that material is compatible with the materials used to form the apparatus 20 and the processes in which the apparatus is used, as described herein.

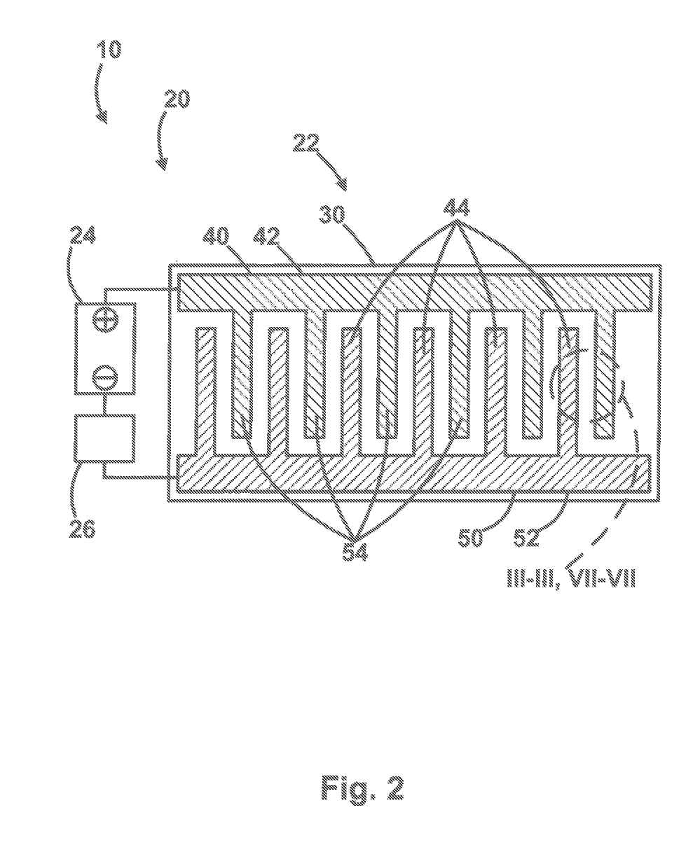

Referring to FIG. 2, the apparatus 20 includes an electrochemical cell 22 and a power source 24, such as a lithium battery, for supplying power to the cell. The electrochemical cell 20 includes a cathode 40 and an anode 50 supported on a solid electrolyte 30, such as a solid polymer electrolyte (“SPE”) or a ceramic type ion conducting electrolyte such as lithium phosphorous oxynitride, (“LiPON”), LISICON and thio-LISICON, (LiₓM_{1-y}M′_{y}S₄; where M=Si, Ge and M′=P, Al, Zn, Ga, Sb), which are the most common inorganic Li⁺ conductors. In FIG. 2, the SPE 30 is a lithium-ion (“Li-ion”) conductor polymer. The electrochemical cell 20 thus has a solid-state construction. The electrochemical cell 20 either: a) does not include a casing, or b) includes a casing that permits contact between the cell and the environment within the enclosure 12.

The SPE 30 is formed of a non-volatile polymer electrolyte material. For example, the SPE 30 could be a Li-ion non-volatile polymer electrolyte material. In one such example, the SPE 30 can be an electrolyte containing a dissolved metal salt, such as a lithium hexafluorophosphate (LiPF₆) solution in polyethylene oxide (“PEO”). The electrochemical cell 20 can thus have a solid state construction. Other salts can be used, such as any of the following:

Lithium bis(trifluoromethane)sulfonamide (CF₃SO₂NLiSO₂CF₃)

Lithium trifluoromethanesulfonate (CF₃SO₃Li)

Lithium tetrafluoroborate (LiBF₄)

Lithium perchlorate (LiClO₄)

Lithium bromide (LiBr)

Alternatively, the SPE 30 can include nanoparticles of alumina or silica, which are known to increase lithium ion conductivity. The SPE 30 can also include non-volatile ionic liquids, such as those based on imidazolium ions, which are also known to increase lithium ion conductivity. One particular example of such a liquid is 1-ethyl-3-methylimidazolium trifluoromethanesulfonate (EMITf).

The solid electrolyte 30 used in the electrochemical cell 20 is not limited to a solid polymer electrolyte construction. The solid electrolyte could, for example, be a mixture of inorganic polymers or could be two layers—an inorganic and a polymer. These configurations can protect the anode material that is not stable by itself toward reaction with gases, such as alloys or low voltage lithium compounds (e.g., lithium titanium oxide “LTO”), which require a much lower voltage to run/charge. The solid electrolyte 30 could also be a mixture of polymers and ionic liquids where both display negligible vapor pressure.

As a further alternative, the electrochemical cell 20 could include an inert separator, such as commercial polyethylene (“PE”) or polypropylene (“PP”) separators, that mechanically supports the electrolyte in its pores. This can be beneficial, for example, in the case where the polymer or mixture is too weak to support the electrodes or to support rolling, folding, or otherwise shaping the cell 20 in the desired manner

The cathode 40 can be made of materials such as nickel (Ni) or copper (Cu), with which lithium does not form alloys at room temperature; of silicon (Si) or tin (Sn), with which lithium is known to form alloys under room temperature conditions; or of carbons, into which Li-ion is known to intercalate. The cathode can incorporate the use of a current collector made out of Cu or Ni onto which silicon and tin can be deposited either as films or in the form of small particles supported on a highly conducting material such as carbon using a non-volatile polymeric binder.

The anode 50 includes a material capable of donating reactive metal ions to the SPE. Examples of such metals are group I metals, such as lithium (Li), sodium (Na), potassium (K), rubidium (Rb), and cesium (Cs). Lithium, however, is the metal best suited for the applications disclosed herein and is therefore preferred. Therefore, the anode 50 could include metallic lithium and any material that contains Li and can lose Li-ions without gas emission, which might be protected by a gas impermeable electrolyte layer preferably inorganic and thus chemically less reactive. For example, the anode 50 can be made of Li⁺ containing material, such as a Li alloy or a lithiated transition metal oxide, such as lithium cobalt oxide (LiCoO₂) and lithium titanium oxide (LTO), which are examples of lithium-ion intercalation materials. Other candidates for constructing the anode 50 include:

lithium iron phosphate (LFP)

lithium manganese oxide (LMO)

lithium nickel manganese cobalt oxide (NMC)

lithium nickel cobalt aluminum oxide (NCA)

Lithium, while preferred, is not the only possible reactive metal. For instance, NASICON (a sodium ionic super conductor material) is a good Na⁺ ion conductor that could be used for the solid electrolyte 30. To use this material as an electrolyte, the anode and cathode materials would have to be formed from matched materials that use Na as the active metal.

This description of the invention illustrates and describes embodiments that utilize lithium as the reactive metal in the electrochemical cell. While lithium is the preferred metal, this description is not meant to be limiting, as those skilled in the art will appreciate that other reactive metals (e.g., those listed above) could potentially be used in the construction of the apparatus 20 and thereby to carry out the reactions and processes described herein.

In the embodiment illustrated in FIG. 2, the SPE 30 has a thin, flat, and elongated planar configuration. The cathode 40 and anode 50 are deposited on the SPE 30. The cathode 40 includes a bus portion 42 that extends along a longitudinal edge of the SPE 30. The cathode 40 also includes a plurality of tabs or fingers 44 spaced along its length and extending transversely from the bus portion 42 in a generally downward direction as viewed in FIG. 2. The anode 50 includes a bus portion 52 that extends along a longitudinal edge of the SPE 30 opposite the bus portion 42. The anode 50 also includes a plurality of tabs or fingers 54 spaced along its length and extending transversely from the bus portion 52 in a generally upward direction as viewed in FIG. 2. The fingers 44, 54 of the cathode 40 and anode 50 are arranged in an alternating and interlocking manner referred to herein and in the art as “interdigitated.” This repeating, interdigitated configuration allows the apparatus to have any desired length.

The SPE 30, cathode 40, and anode 50 can be extremely thin, e.g., in the range of several hundredths or thousandths of an inch thick. The electrochemical cell 20 can thus have a correspondingly thin construction. The SPE 30, cathode 40, anode 50, and, thus, the apparatus 20, can, of course, be thicker. Advantageously, this thin, elongated, planar configuration, in combination with its material construction, allows the electrochemical cell 20 to be bent, rolled, folded, and otherwise manipulated to assume a desired shape, configuration, or form. For example, the electrochemical cell 20, having this construction, can be made to conform to the shape of a portion of the enclosure 12 (see FIG. 1) in which it is implemented.

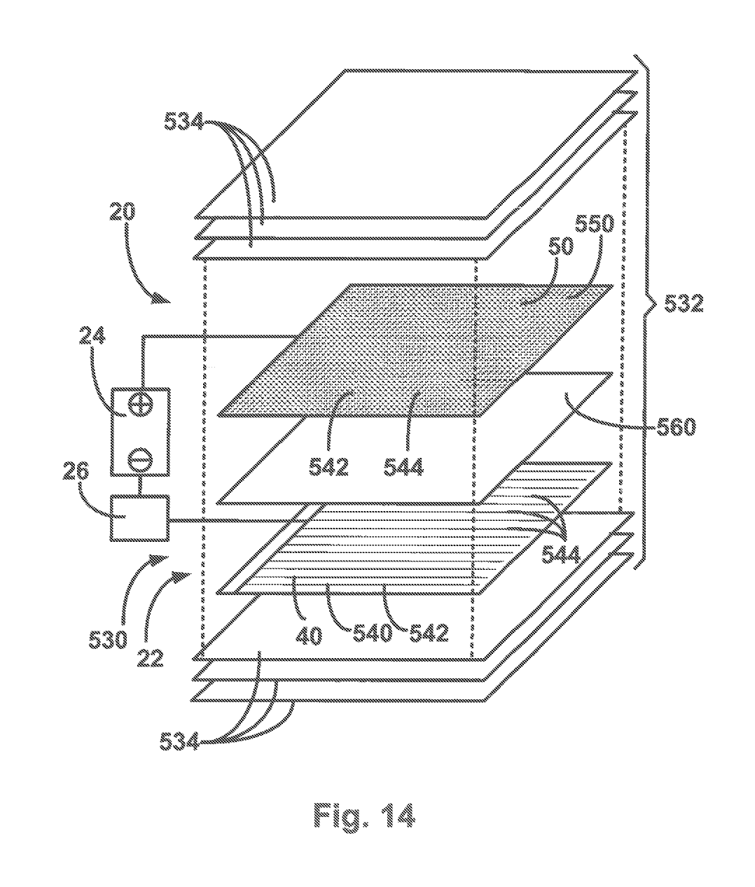

The thin film electrochemical cell construction illustrated in FIG. 2 is but one illustrative example thin film construction of the cell. The electrochemical cell 20 could have alternative thin film constructions, such as that illustrated in FIG. 14 and described in reference thereto. The electrochemical cell 20 could also have configurations and/or constructions alternative to the thin film configuration. For example, the electrochemical cell 20 can have other film configurations or could be constructed in the form of a pellet, cylinder, block, or any other desired configuration having electrodes and electrolyte arranged in a manner that is consistent with the operation described herein.

According to the invention, the electrochemical cell 20 is adapted to consume the gases, i.e., air or its gaseous non-noble constituents, within the enclosure 12 through an electrochemical reaction, via one or more chemical reactions with electrochemically generated lithium, or lithium alloys, or chemical reactions between the products of these reactions and atmospheric components. The electrochemical reaction produces metallic lithium that is exposed to the gases in the enclosure 12. The metallic lithium reacts with and consumes those gases. The electrochemical cell 20 consumes the gases in the enclosure 12 through an electrochemical reaction that takes place when a voltage is applied to the cell by the source 24. Operation of the apparatus 20 can also be achieved by controlling the current supplied to the electrochemical cell 20 by the power source 24.

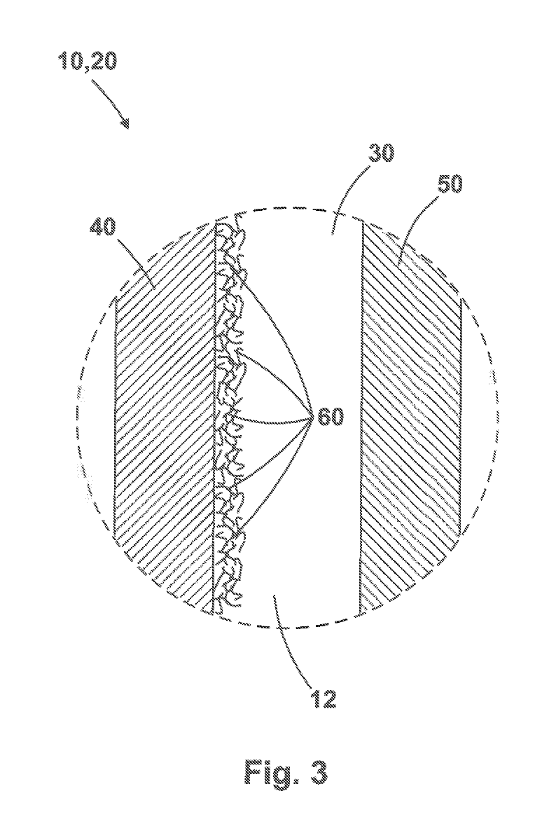

FIG. 3 illustrates the operation of the electrochemical cell 20 in accordance with a first embodiment of the invention. In this embodiment, the cathode 40 is formed of a material that does not form alloys with lithium, such as nickel or copper. Because of this construction, the electrochemical reaction that takes place during operation of the electrochemical cell 20 results in the electrodeposition of the Li metal from the lithium-ion SPE 30 onto the cathode 40, while the anode 50 releases Li⁺ ions into the SPE. The electrochemical cell 20, being in contact with the environment within the enclosure 12, allows the gases within the enclosure to permeate through the SPE 30 and thus react with the electrodeposited Li metal and/or its alloys on the cathode 40. Since permeation can be slow, the cathode 40 can have a porous construction to facilitate a less restricted path for gases in the enclosure to reach the Li deposits on the cathode. Since metallic Li electrodeposits are often dendritic in shape, dendrites 60 formed on the cathode have large specific areas that are exposed to the environment within the enclosure and thus provide optimum conditions for promoting reactions with the gases in the enclosure 12.

The reactions between metallic Li and the gases within the enclosure would include:

6Li+N₂→2Li₃N;

4Li+O₂→2Li₂O;

2Li+H₂O→LiOH+LiH

Li₂O+H₂O→2LiOH

4Li+O₂+2H₂O→4LiOH

2Li+2H₂O→2LiOH+H₂

The amount of lithium available for electrodeposition on the cathode 40 is determined primarily by the amount of Li⁺ ion contained within the anode 50 which, advantageously, can be selected to be equal to or greater than the amount required to react with the entire volume of gas present within the enclosure 12. Alternatively, the amount of Li⁺ ion contained within the anode 50 can be selected to react with a desired amount or portion of the volume of gas present within the enclosure 12. Additionally, the amount of lithium can be selected to leave some left unconsumed after the initial gas consumption. Advantageously, this excess lithium can consume gases that subsequently enter the enclosure 12, for example, due to leakage.

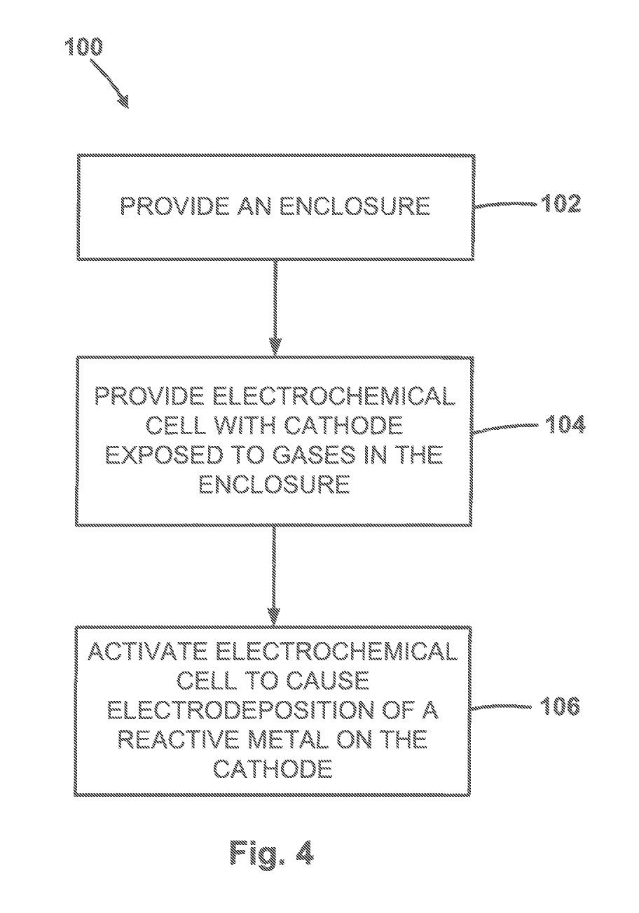

From the above, and referring now to FIG. 4, it will be appreciated that the system 10 and apparatus 20, having the construction and operation described with reference to FIG. 3, performs a method 100 for consuming gases in an enclosure. The method 100 includes the step 102 of providing an enclosure, and the step 104 of providing an electrochemical cell with a cathode exposed to the gases in the enclosure. The method 100 further includes the step 106 of activating the electrochemical cell to cause electrodeposition of a reactive metal on the cathode. The reactive metal on the cathode reacts with the gases in the enclosure to consume the gases in the enclosure.

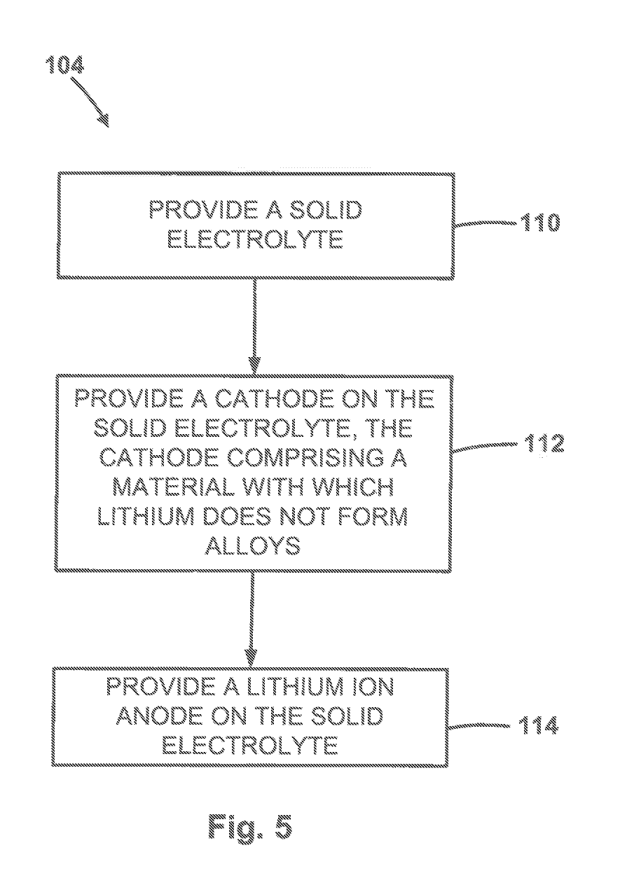

Referring to FIG. 5, the step 104 of providing an electrochemical cell includes the step 110 of providing a solid polymer electrolyte (“SPE”). The step 104 also includes the step 112 of providing a cathode on the SPE, the cathode comprising a material with which lithium does not alloy, such as nickel or copper. The step 104 also includes the step 114 of providing a lithium ion anode on the SPE (e.g., a lithium alloy anode or a lithiated transition metal oxide anode).

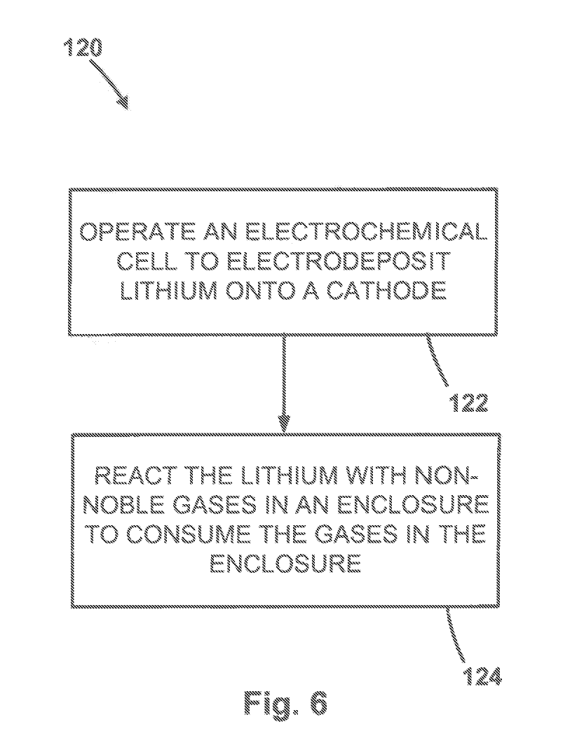

In another aspect, referring now to FIG. 6, the system 10 and apparatus 20 having the construction and operation described with reference to FIG. 3, performs a method 120 for consuming gases in an environment. The method 120 includes the step 122 of operating an electrochemical cell to electrodeposit lithium onto an electrode (cathode). The method 120 also includes the step 124 of reacting the lithium with non-noble gases in the enclosure to consume those gases.

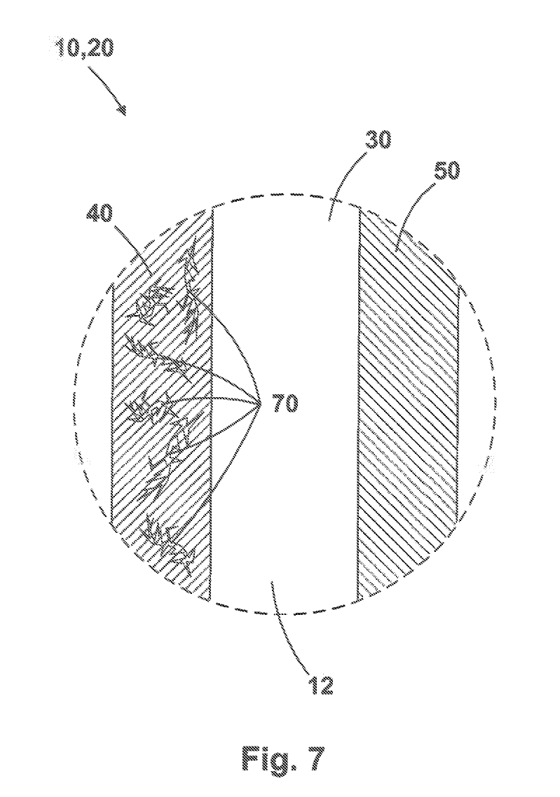

FIG. 7 illustrates the operation of the electrochemical cell 20 in accordance with a second embodiment of the invention. In this embodiment, the cathode 40 is formed of a material that forms alloys with lithium, such as silicon or tin. Because of this construction, the electrochemical reaction that takes place during operation of the electrochemical cell 20 differs from that shown and described with reference to FIG. 3.

In the embodiment of FIG. 7, the lithium reaction with silicon is an alloying reaction that results in the formation of a lithium alloy. The reaction starts at the surface and modifies the crystal structure (lattice) of the host material, i.e., Si or Sn. Alternatively, depending on the materials used to form the cathode, instead of alloying, the lithium could intercalate into an activated cathode material, forming LiC6 (lithium in graphite). In either case, the lithium alloy/intercalated lithium reacts with and consumes the gases in the enclosure 12.

Again, as with the first embodiment, the reactions between the lithium in the lithium alloy/intercalated lithium and the gases within the enclosure would include (where the alloying element has been omitted for clarity):

6Li+N₂→2Li₃N;

4Li+O₂→2Li₂O;

2Li+H₂O→LiOH+LiH

Li₂O+H₂O→2LiOH

4Li+O₂+2H₂O→4LiOH

2Li+2H₂O→2LiOH+H₂

Similarly, the amount of lithium available for alloying with the cathode 40 is determined primarily by the amount of Li⁺ ion contained within the anode 50 which, advantageously, can be selected to be equal to or greater than the amount required to react with the entire volume of gas present within the enclosure 12. Alternatively, the amount of Li⁺ ion contained within the anode 50 can be selected to react with a desired amount or portion of the volume of gas present within the enclosure 12. Additionally, the amount of lithium can be selected to leave some left unconsumed after the initial consumption of gases. Advantageously, this excess lithium can consume gases that subsequently enter the enclosure 12, such as those entering due to leakage.

In this embodiment, the cathode 40 could be constructed of an electrically conductive mesh material (e.g., Cu or Ni) onto which silicon or tin can be deposited as films or in the form of small particles supported on a highly conductive material, such as carbon, using a non-volatile polymeric binder. This construction would improve the current conducting properties of the cathode 40.

Incorporation of lithium into the cathode 40 to form an alloy causes the volume of the cathode 40 to increase, which can result in mechanical stresses that lead the cathode structure to crack, fissure, or otherwise rupture. This possibility is shown in FIG. 7. Referring to FIG. 7, these cracks/fissures 70 could be advantageous in that they could further expose the lithium alloy contained in the cathode 40 to the gases in the enclosure 12 and furthers the reaction with those gases.

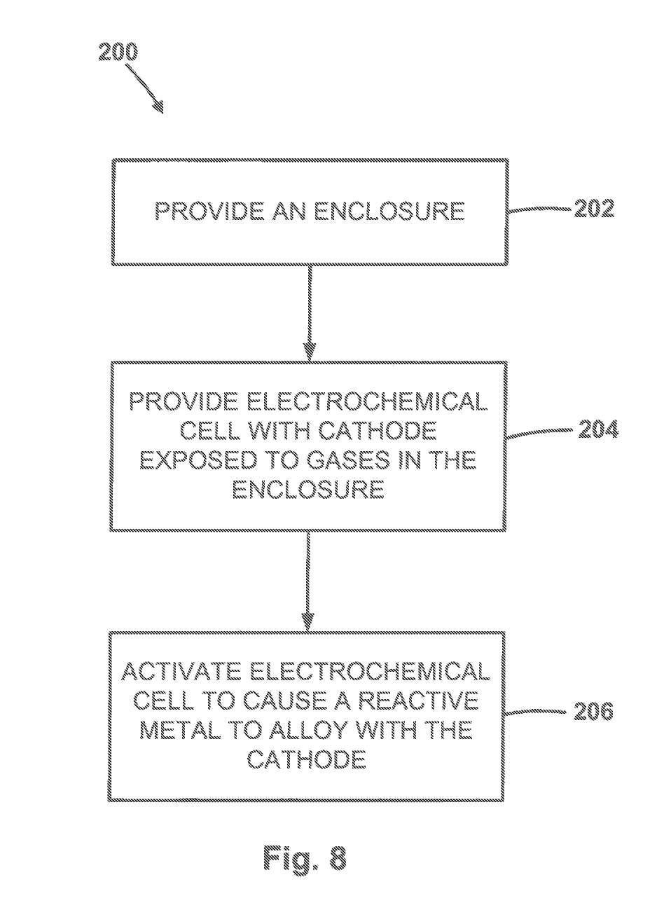

From the above, and referring now to FIG. 8, it will be appreciated that the system 10 and apparatus 20 of the second embodiment shown and described in reference to FIG. 7 are used to perform a method 200 for consuming gases in an enclosure. The method 200 includes the step 202 of providing an electrochemical cell with a cathode exposed to the gases in the enclosure. The method 200 further includes the step 206 of activating the electrochemical cell to cause a reactive metal to alloy with the cathode of the electrochemical cell. This alloy reacts with the gases in the enclosure.

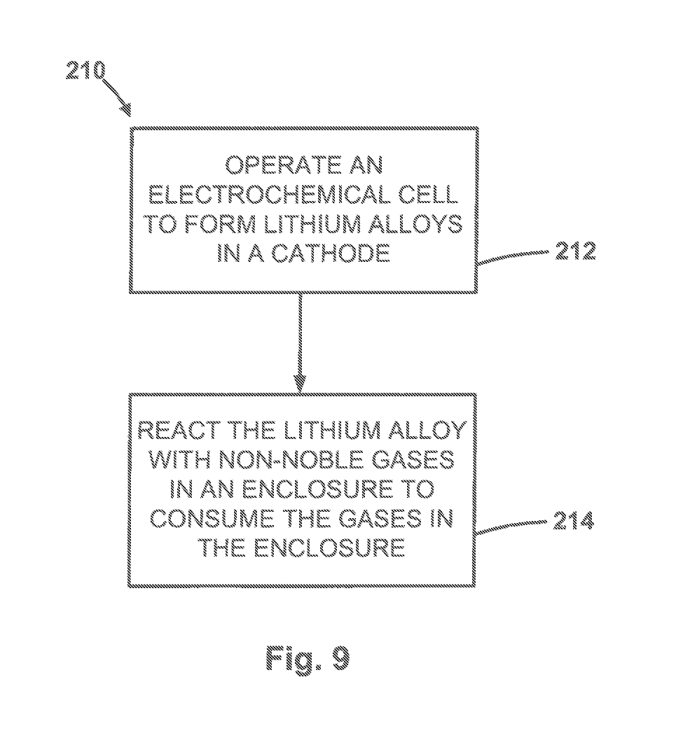

Referring to FIG. 9, it will be appreciated that the system 10 and apparatus 20 of the second embodiment are also used to perform a method 210 for consuming gases in an enclosure. The method 210 includes the step 212 of operating an electrochemical cell to form lithium alloys on a cathode. The method 210 also includes the step 214 of reacting the lithium alloy with non-noble gases in the enclosure to consume those gases.

From the above, those skilled in the art will appreciate that the apparatus 20 allows for the consumption of gases in an enclosure 12. The electrochemical cell 22 is operable to consume the non-noble gases in the enclosure 12. Thereafter, the electrochemical cell 22 can be used to maintain the levels of those gases in the enclosure to a desired level. Since the total amount of Li in the anode 50 will control the amount of gas the apparatus 20 is capable of removing, its size can be selected accordingly.

Depending on the materials used to construct the electrochemical cell 20, the cell may require the addition of certain components to facilitate its operation. For example, in order to raise the ionic conductivity of solutions of a Li salt in PEO, the temperature of the PEO may be raised up to several tens of degrees centigrade. To accomplish this, the cell may include a heater. Once the system begins to work and the pumping action starts, the ability of the heater to heat up the cell will increase as there will be very little or no path for heat dissipation (none in the case of a self contained, battery powered unit, and very little in the case of wires that connect the cell to the outside world). The latter would be avoided by having the battery internal to the enclosure and well isolated thermally.

The sealed enclosure 12 can be formed with the apparatus 20 disposed therein, and can be inert until activated from outside the enclosure 12. To accomplish this, the apparatus 20 can include actuator 26, which is illustrated schematically because it can take on various forms. For example, the actuator 26 can include electronics or circuitry that is adapted to activate the apparatus remotely and/or wirelessly. Advantageously, the electronics/circuitry of the actuator 26 can deactivate the apparatus 20 and subsequently reactivate the apparatus, for example, due to a pressure increase within the enclosure 12. To this end, the electronics/circuitry of the actuator 26 can be adapted to monitor the pressure within the enclosure 12.

As another example, the actuator 26 can be configured for non-electronic manual or mechanical activation. This can be advantageous, for instance, in implementations where cost is a concern. In this implementation, the actuator 26 can include, for example, a rupturable member that, when destroyed, completes the circuit between the source 24 and the electrochemical cell 22. Alternatively, the actuator 26 can be a removable member that, when removed manually, completes the circuit between the source 24 and the electrochemical cell 22. This can, for example, be a removable strip or tape that insulates the source 24 from the electrochemical cell 22. As a further alternative, the actuator can be a mechanism that is actuated magnetically to complete the circuit between the source 24 and the electrochemical cell 22. This can be achieved, for example, in a manner similar to that used to secure/release magnetic security tags commonly found in department stores and the like.

In yet another example, the actuator 26 can incorporate the use of radiofrequency (“RF”) transducers/tags and interrogators/receivers. For instance, the actuator 26 can include an RF tag/switch that allows the electrochemical cell 22 to be activated/deactivated via an RF interrogator/receiver. The actuator 26 can also include an RF transducer that can return any sensed indication from within the enclosure 12, such as a pressure, temperature, oxygen level, etc. Thus, once the gases within the enclosure are consumed initially, the electrochemical cell 22 could be deactivated remotely via RF control. Thereafter, conditions in the enclosure 12 can be monitored periodically and, when necessary, the electrochemical cell 22 can be reactivated via RF control.

In a further example, the power supply 24 could be external to the enclosure 12, and fed to the electrochemical cell 22 via sealed electrical feedthroughs in the walls of the enclosure 12, e.g., sockets or pins, that allow fully controlled operation of the apparatus external to the enclosure.

As yet another example, the power supply 24 and/or actuator 26 could include a wireless inductive charging power supply that uses an electromagnetic field to transfer energy from a charging unit outside the enclosure 12 to the electronics in the enclosure. In this instance, a charging unit with an inductive transmitting coil would generate an electromagnetic field that excites an inductive receiving coil component of the power supply 24 in the enclosure. These coils cooperate to form an inductive coupling for powering or charging the electrochemical cell 20.

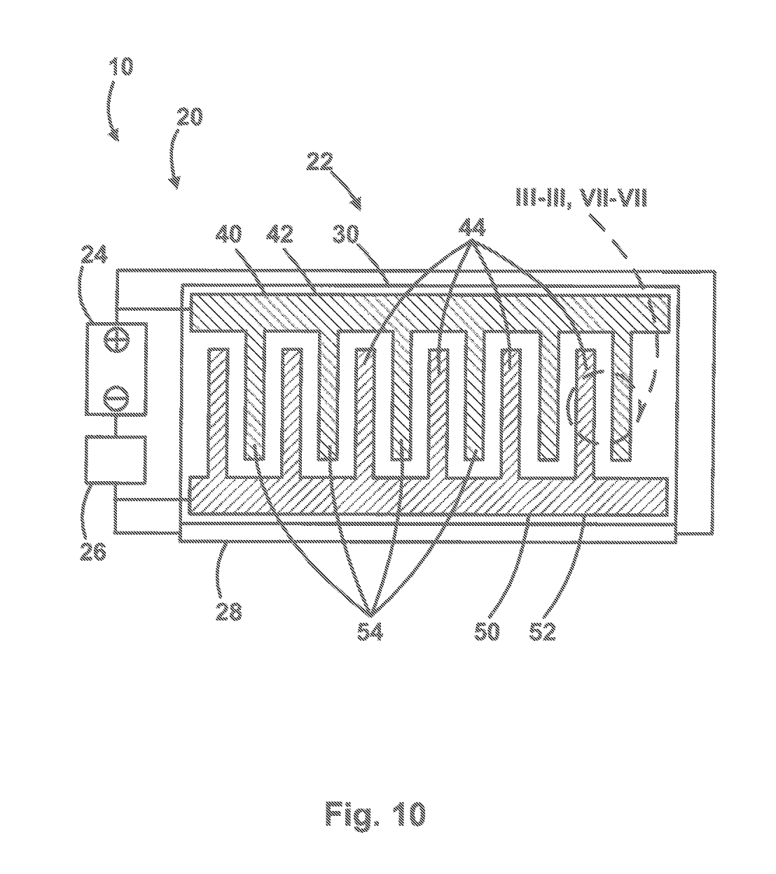

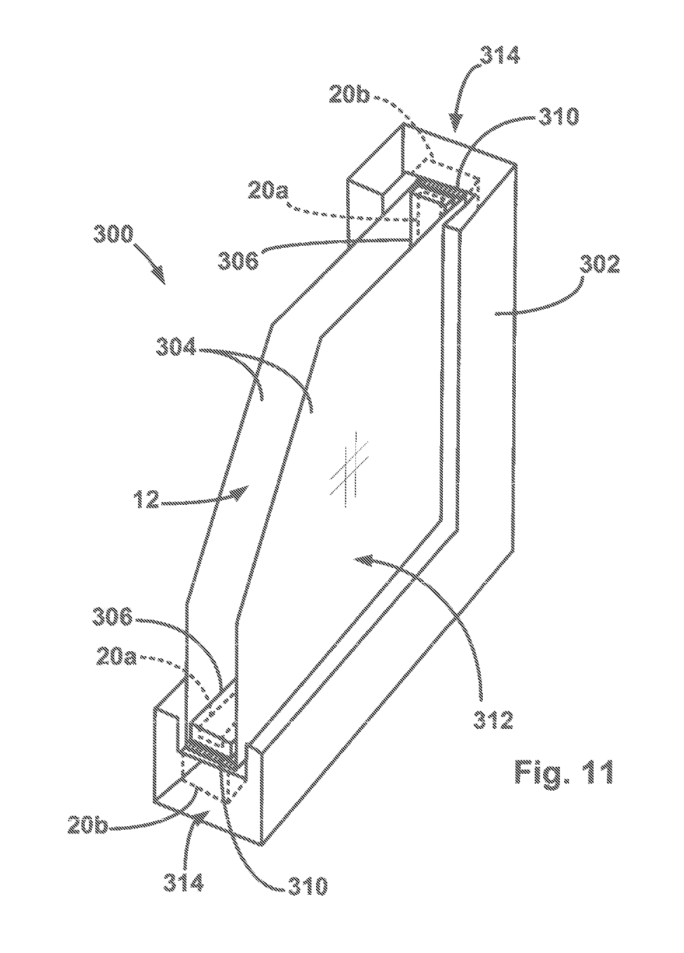

According to another aspect of the invention, the apparatus 20 can include a heater 28 for heating the electrochemical cell 22 within the enclosure 12. This is shown in FIG. 10. The apparatus 20 shown in FIG. 10 is identical to the apparatus shown in and described with reference to FIGS. 1-9, with the heater 28 being added to the embodiment of FIG. 10. The heater 28 can have any configuration consistent with the description of the invention set forth herein. For example, the heater 28 can be a simple resistive heating element that is an integral portion of the apparatus 20 located within the enclosure 12. Alternatively, the heater could be an electromagnetic radiation (e.g., microwave) heat source located outside the enclosure 12.

In the example configuration illustrated in FIG. 10, the heater 28 is connected to and powered by the power source 24. The heater 28 could, however, be powered via an alternative source, such as a magnetic field power source that powers the heater via induction. As a matter of convenience and economy, the manner in which the heater 28 is powered and operated can be selected to coincide with the manner in which the electrochemical cell 22 is powered and operated. Thus, as shown in FIG. 10, the apparatus 20 can be configured so that both the electrochemical cell 22 and the heater 28 are powered by the power source 24 and actuated by the actuator 26.

In operation, the heater 28 functions to raise the temperature of the electrochemical cell 22 during operation. The heater 28 can be configured and arranged to have the ability to raise the temperature of the electrochemical cell 22 in the order of tens of degrees centigrade or more. Since temperature affects the rates of metal deposition and the microstructure of electrodeposits, the ability to control the temperature of the electrochemical cell 22 can allow for controlling the rates of the resulting reactions. It therefore follows that including the heater 28 and implementing the ability to control its function allows for tailoring the operation of the electrochemical cell 22 in order to produce desired results, i.e., desired rates and degrees of gas consumption.

From the description set forth herein, those skilled in the art will appreciate that the system, method, and apparatus of the invention relates to the concept of electrochemically producing a material, either an element, alloy, or chemical compound, that will react with atmospheric components for the purpose of consuming gases in an enclosure. The electricity for producing this electrochemical reaction can be supplied by any suitable source, such as a battery, capacitor, fuel cell or any other device capable of generating electricity. In certain implementations, the electricity could be supplied via a power supply connected by cord or cable to an electrical outlet.

The materials produced through the chemical reaction can be the alkali metals described above (e.g., lithium) and can also include alkaline earth metals, such as magnesium. In this case, metallic magnesium could be electroplated on a metallic grid or foam electrode using a magnesium salt dissolved in polyethylene oxide incorporating a non-volatile ionic liquid as the electrolyte (see, for example, Kumar et al. Electrochimica Acta 56 (2011) 3864-3873), and a cathode containing, for example, nanoscale Chevrel Mo₆S₈ in powder form (see, for example, Ryu, A.; Park, M. S.; Cho, W.; et al. Bulletin of the Korean Chemical Society 34, 3033-3038 (2013) or one of many other materials known to intercalate magnesium ion (see, for example, Gershinsky, G.; Yoo, Hyun D.; Gofer, Y.; et al. Langmuir 29, 10964-10972 (2013)).

In the case of magnesium, the reactions between the magnesium alloy and the gases within the enclosure would include (where the alloying element has been omitted for clarity):

3Mg+N₂→Mg₃N₂;

2Mg+O₂→2MgO;

MgO+H₂O→Mg(OH)₂

-or-

2Mg+O₂+2H₂O→2Mg(OH)₂

Transition metals can also be used. Examples of these are manganese, iron, cobalt, nickel, copper, and zinc. Other transition metals can be used, although their uses may be cost prohibitive. Additionally, rare earth elements (i.e., the lanthanides plus scandium and yttrium) can also be used.

These transition metals can include nanoparticles or nanodomains of manganese, iron, cobalt, nickel, copper, and zinc which can be generated by the electrochemically induced conversion of salts, such as fluorides, oxides, or sulfides of these metals in the presence of lithium ions in the electrolyte which would produce the corresponding lithium salts according to the generalized reaction:

MXₙ+nLi⁺+ne⁻→nLiX+M

where M represents a transition metal (e.g., Mn, Fe, Co, Ni, Cu, or Zn), X represents oxygen, sulfur, or fluorine, n represents the subscript appropriate for the compound or the proper coefficient for balancing the reaction.

In one particular example, metals such as aluminum and zinc and some transition metals of the first raw, e.g. Fe, in nanometric form readily reacts with oxygen to form oxides in an irreversible fashion. In this instance, the above equation would be:

4Fe+3O₂=2Fe₂O₃

This chemistry is found in so-called metal-air batteries. and thus could be used as the power source 24 for the electrochemical cell 22 in the sealed enclosure 20 (see FIG. 1) would therefore advantageously remove oxygen from the enclosure while simultaneously powering the cell to remove other gases. Also envisioned is the possibility of flushing the enclosure 20 with a single gas or a mixture of gases prior to it being sealed In fact, any of the electrochemical cells described herein could be used under conditions in which the enclosure 20 would be flushed with inexpensive gases in addition to or other than oxygen, such as carbon dioxide. The gases could be introduced during construction of the enclosure, prior to it being sealed. When the enclosure is filled with the gas, it can be sealed with the electrochemical cell and power source installed therein. Once the cell/power source is activated, the gas will be consumed through the reactions described herein. Advantageously, this can avoid leaving noble gases, such as argon, in the enclosure. Since noble gases will not react with the metals in the electrochemical cell, they cannot be removed electrochemically. Removing noble gases such as argon prior to sealing the enclosure solves this and, in doing so, allows the electrochemical reaction to form a more complete vacuum.

As a further alternative, a water aspirator or a mechanical pump could be used to reduce the pressure in the sealed enclosure prior to activating the electrochemical cell. This would serve to reduce the pressure in the enclosure.

### Additional Implementations of the Apparatus

Since the system 10 and apparatus 20 are operable according to the methods described herein to consume gases in an enclosure, its function can be and is dictated at least partially by its implementation. Examples of such functions are described in the following paragraphs.

Vacuum Formation and/or Maintenance

According to one example implementation, the system 10 and apparatus 20 can be used to form and/or maintain a vacuum simply by implementing the apparatus in an enclosure 12 that is appropriately constructed and sealed so as to support a vacuum therein. The apparatus 20, when activated, it produces the material, e.g., lithium or magnesium, which reacts with and consumes non-noble gases in the enclosure 12 to form and/or maintain the desired vacuum. One product for which this may be particularly advantageous are vacuum thermal insulation panels (“VIPs”).

VIPs are a form of thermal insulation that provides an excellent level of thermal resistance (R-value) in a package that is very thin in comparison with the thickness of comparable conventional insulating materials (e.g., rolls and batts, loose-fill, rigid foam, and foam-in-place insulation). VIPs having a thickness of less than an inch can provide an R-value that would require several inches or even feet of traditional thermal insulation materials.

Because of these features, VIPs are attractive insulation alternatives in a wide range of applications where space and/or high thermal resistance is desired. Potential applications range from residential and commercial building construction, commercial and industrial furnace/refrigeration applications, medical storage and transport, residential appliances, etc. The high R-value, low thickness features of VIPs beneficially reduces the space considerations required for engineering these products and, for example, can lead to refrigerators with more storage, ovens with larger capacities, and medical supplies that can last longer in extreme field conditions.

VIPs include a gas-tight or nearly gas-tight enclosure, surrounding a rigid or semi-rigid core material, in which the air has been evacuated to form a vacuum. The VIP is typically constructed of overlying gas impermeable membrane panels that are sealed around their peripheries to define the enclosure. The core material is constructed of a highly porous material. The core material can have various material constructions and configurations. For example, the core material can be a panel of material (e.g., a sheet of glass fiber) positioned between the membranes or a bulk material (e.g., a loose fiber or foam) distributed evenly between the membranes. When the air is evacuated from the enclosure, the external pressure applied to the membranes compress the core which, in response, maintains some degree of spacing between the membranes. The porous core material provides the space between the membranes in which the vacuum is formed.

VIPs are costly in comparison to conventional forms of thermal insulation materials. One factor that lends to this cost differential is the high cost of manufacture of the VIPs. These manufacturing costs are driven not only by high material costs, but also by costly manufacturing equipment. The vacuum pumps traditionally used to evacuate air from the VIPs are costly pieces of equipment. Additionally, because the vacuum pumps require access to the VIP enclosure to draw the vacuum, maintaining and completing the seal between the membranes after the pump is removed requires additional equipment and cost.

Implementing the system 10 and apparatus 20 in a VIP construction advantageously can help form and maintain the vacuum in the panel and can also help account for gases entering the panel due to leakage and/or degassing of the polymers used to construct the panel.

### Argon Filled Insulated Windows

Another such application for which the system 10 and apparatus 20 can be implemented relates to the field of argon filled insulated windows. A illustration depicting an example construction of an argon filled window is shown in FIG. 11. Referring to FIG. 11, a multi-pane window assembly 300 includes a frame 302 that supports a pair of spaced panes 304 of glass. The two-pane construction of the window assembly 300 is for illustrative purposes and is not meant to be limiting. The multi-pane window assembly 300 could, for example, include three or more spaced panes of glass. The window assembly 300 also includes one or more spacers 306 that maintain the spaced relationship of the panes 304. The frame 302 and spacers 306 extend about the periphery of the window assembly 300, defining an opening 310 across which the panes 304 extend.

An edge seal 310 extends about the periphery of the spaced panes 304. In some configurations, the edge seal 310 can be formed as part of the spacers 306. In other configurations, the edge seal 310 can be a component separate from the spacers 306. In this example implementation of the apparatus 20, the edge seal 310 and the panes 304 define the enclosure 12. In this embodiment, the panes 304, edge seals 310, and, thus, the enclosure 12 is gas-tight or substantially gas-tight to the extent that it is capable of maintaining within its confines a volume of argon gas for an extended period of time, such as 20 years or more.

Since argon has a lower thermal conductivity than air, the argon-filled window assembly can have a lower thermal conductivity than other window designs. This is not surprising, as the heat capacity of a monoatomic gas such as argon is lower than diatomic gases (e.g., oxygen and nitrogen) and triatomic gases (e.g., carbon dioxide and water).

While great care is exercised to ensure a complete seal of the enclosure 12, over time, any seal can deteriorate and leak. In the field of argon filled insulated windows, questions do exist with regard to the effectiveness of window sealants. These products are both expected and required to serve a long useful life, so there exists a need to provide quality products backed by long-term warranties. Therefore, there is a need to identify and implement better sealants and also to account for the fact that no seal is perfect.

When seals fail in argon filled insulated windows, argon escapes the enclosure 12 and air enters the enclosure. Additionally, polymer based materials can be prone to a phenomenon, referred to as “de-gassing,” in which the polymer material itself can release gases over time. Polymer materials exposed to the sealed enclosure 12 can thus release gases into the sealed enclosure due to de-gassing. Both of these factors—leakage and de-gassing—would introduce gases into the sealed enclosure 12 that would lead to an overall increase in the heat capacity of the window, which undesirably lowers its thermal insulating capabilities. Since polymer exposure to the enclosure 12 would likely be limited to the area of the seals, this exposure might be minimized through careful material selection and design of the seals. The possibility of leakage through the seals, however, is an issue that cannot be left unaddressed.

According to the invention, the apparatus 20 can be positioned at least partially inside the sealed enclosure 12 of the argon filled insulated window assembly in order to account for leakage and any de-gassing. When activated, the apparatus 20 will operate in the manner described above to remove all of the diatomic and triatomic atmospheric components that have leaked into the sealed enclosure 12 and will thus mitigate to a large extent the degradation due to the leakage. Additionally, the apparatus 20 will consume any of the gases that have entered the enclosure 12, whether through leakage or de-gassing. Since the rate of leakage and/or de-gassing will be extremely small, the reduction in the overall pressure inside the enclosure 12 will be negligible. This is desirable because a decrease in pressure would cause the glass panes to deflect, which could compromise the structural integrity of the window. Additionally, some of the atmospheric components entering the sealed enclosure 12 will be argon which, at least to some extent, will help account for and replace argon lost due to the leakage.

The reactions that take place within the sealed enclosure of the window, thus can include the following:

6Li+N₂→2Li₃N;

4Li+O₂→2Li₂O;

2Li+H₂O→LiOH+LiH

Li₂O+H₂O→2LiOH

4Li+O₂+2H₂O→4LiOH

2LiOH+CO₂→Li₂CO₃+H₂O

2Li+2H₂O→2LiOH+H₂

In the example argon filled insulated window implementation of the apparatus 20, the panes 304, which define the vast majority of the enclosure 12, are necessarily transparent. Therefore, the configuration and positioning of the apparatus 20 within the structure of the window 300 is not a trivial matter. Because of this, portions of the apparatus 20 may require integration into the structure of the window 300, such as the frame 302 or the spacers 306.

For example, since the spacers 306 have portions that are exposed to the interior of the enclosure 12, it may be advantageous to form at least a portion of the apparatus 20 integrally with or on the spacers. In this implementation, the apparatus 20 could extend along any portion or segment of the spacers 306. This portion of the apparatus 20 is shown generally at 20a in FIG. 11. Additionally, since the window frame 302 typically can have an extruded metal, plastic, or polymeric construction, there may be some interior space 314 that is available to house a portion of the apparatus 20. This portion of the apparatus 20 is shown generally at 20b in FIG. 11. In this implementation, the portion 20a of the apparatus can include the electrochemical cell 22, so as to expose the lithium electrodeposited on the cathode to the gases in the enclosure 12. In this implementation, the portion 20b of the apparatus can include the power source 24 and the actuator 26.

In view of the above, according to the invention, where the sealed enclosure 12 is the sealed space between the panes of an argon-filled window 300, the apparatus 20 having at least a portion disposed therein will serve to help maintain the thermal insulating properties of the window by removing any non-noble atmospheric components that may leak into the sealed enclosure 12 of the window, or any gases that may enter the enclosure due to polymer de-gassing. As a further advantage, the inclusion of the apparatus 20 in the argon-filled window can allow for the use of polymers for its construction, sealing, etc., where use of those materials had heretofore been impossible due to concerns over de-gassing.

### On-Demand Gas Removal

In some applications for the apparatus 20, the primary concern may not necessarily be to remove all non-noble gases from the enclosure 12. Removal of certain gases, such as oxygen, nitrogen, carbon dioxide, carbon monoxide, a combination of these gases, or even air itself, may be the primary focus. In another particular example, the primary focus or purpose for the inclusion of the apparatus 20 may be to remove water, i.e., water vapor, from the enclosure 12.

There are many applications in which it is desirable to avoid exposing certain products to even extremely small amounts of water. For certain products, such as electronic components, microelectromechanical systems, MEMS, pharmaceuticals, certain chemicals or chemical compounds, avoiding exposure to even extremely small amounts of oxygen or water in the form of water vapor or humidity may be critical. For instance, in certain applications, barrier films are used to isolate components not necessarily from air but, more importantly, water vapor in the air. In this situation, exposure of the products to gases and atmospheric components is perfectly fine and non-harmful. It is the oxygen or water vapor in these gases, i.e., the humidity that needs to be controlled.

According to another application of the system 10 and apparatus 20 is to control the amount of a particular gas or gases, such as air, carbon dioxide, nitrogen, oxygen, water, i.e., the water vapor or humidity, in an enclosure 12. In this application, the enclosure 12 does not necessarily need to be sealed although, to the extent that such sealing can help control the presence of the gas that is to be consumed, sealing may be desired. The lithium metal deposited by the apparatus 20 will always react with any non-noble gas with which it comes into contact. Therefore, to selectively remove any gas from the enclosure 12 requires that the apparatus 20 be selectively actuated. This selective actuation will help to eliminate or minimize unnecessary operation of the apparatus 20 at those times when the level of the undesirable gas within the enclosure 12 is at an acceptable level.

One way to achieve this is to adapt the actuator 26 so that the apparatus 20 is actuated in response to the presence of the target gas within the enclosure 12 reaching a predetermined level. In the case where water vapor is the target gas, the actuator 26 would include a humidity sensor actuatable to activate the apparatus 20 in response to sensing the presence of a threshold amount of water vapor in the enclosure 12. In the case where another gas or gases are the targets, then the actuator 26 could be adapted with sensors for detecting those other gases, such as oxygen sensors, carbon dioxide sensors, or carbon monoxide sensors.

When the apparatus is actuated, the reactions that take place can include the following:

6Li+N₂→2Li₃N;

4Li+O₂→2Li₂O;

2Li+H₂O→LiOH+LiH

Li₂O+H₂O→2LiOH

4Li+O₂+2H₂O→4LiOH

2LiOH+CO₂→Li₂CO₃+H₂O

2Li+2H₂O→2LiOH+H₂

The enclosures 12 in which the apparatus 20 is adapted to remove gases can come in a virtually limitless variety of shapes, sizes, and forms. Customarily, for components that are highly sensitive to water exposure, an enclosure 12 is built around those components to reduce or prevent the ingress of gases, including water vapor. These enclosures may, for example, employ one or more layers of a polymer film with adhesives used to form a seal, such as an edge seal, that completes the enclosure 12. In certain applications, however, components are so sensitive to water exposure that further protective steps are warranted.

In one such application, organic light emitting diode (OLED) displays are known to be particularly sensitive to water, the exposure to which can destroy the panel. In this particular application, it would be especially advantageous to implement the apparatus 20 to remove moisture from the air in the enclosure 12 in which the OLEDs are housed. In accordance with the invention, this can be done in an on-demand fashion, in response to the humidity in the enclosure 12 reaching a predetermined level. This can be done, for example, by including a humidity sensor in the actuator 26.

In this application, the apparatus 20 operating on principles identical to those described above in regard to removing atmospheric components and other gases from an enclosure 12 can eliminate the need to rely on desiccants or other similar materials to remove moisture from the enclosure or prevent moisture from entering the enclosure. This can be advantageous because desiccants and other similar materials are finite in capacity and can become saturated or otherwise spent. Additionally, these materials are not capable of being controlled in an on-demand fashion, and therefore remove/absorb water from the air even if the air humidity is at an acceptable level and water removal is unnecessary.

The amount of space within the enclosure 12 can be small, even when compared to the size or footprint of the enclosure itself. For example, where the enclosure 12 is a VIP vacuum insulating panel, as described above, the space within the enclosure can be occupied significantly by the core material within the enclosure. Similarly, in the case where the enclosure 12 is a display panel, such as an OLED display, the enclosure can be defined, at least partially, by closely spaced overlying film layers or panels. In this instance, while the enclosure 12 spans the space of the display or more, the close spacing between the overlying films results in a relatively small volume within which to control the atmosphere.

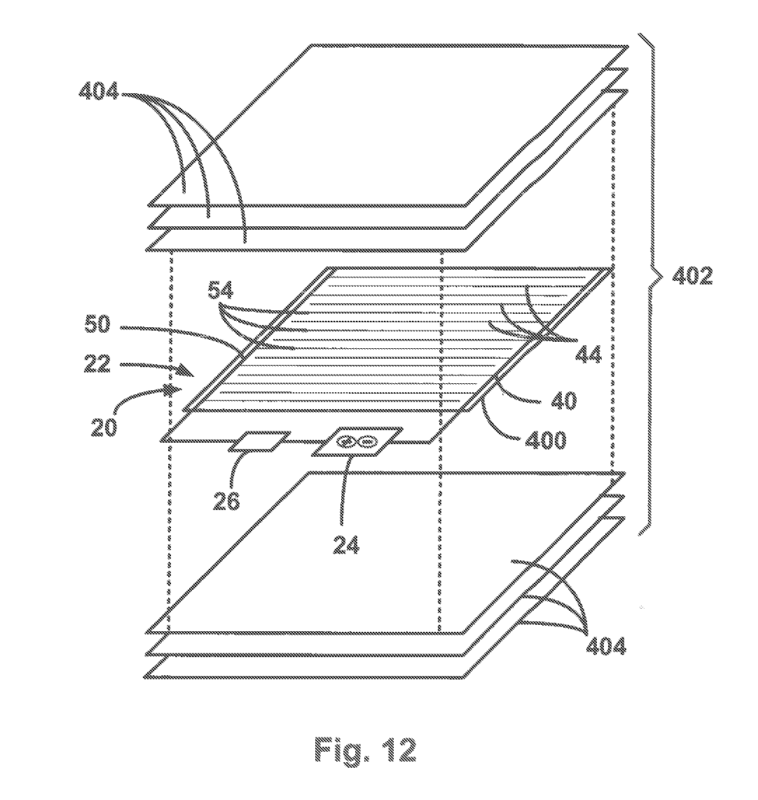

One implementation in which the apparatus 20 or a portion thereof has a thin layer construction is illustrated in FIG. 12. Referring to FIG. 12, the apparatus 20 can be constructed, at least in part, in accordance with the thin film construction described herein above with reference to FIGS. 2 and/or 14. Thus, in the apparatus 20 of the embodiment illustrated in FIG. 12, the electrochemical cell 22 is formed as a thin film 400, and can have any of the various configurations described herein with reference to FIGS. 2 and/or 14.

In the embodiment of the apparatus 20 depicted in FIG. 12, the electrochemical cell 22, having the thin film 400 construction, can be implemented in a variety of manners. For example, the apparatus 20 can be implemented in a multilayer film panel construction, as shown in FIG. 12. In this implementation, the thin film 400 forms one or more layers of a multilayer panel 402 that includes one or more layers 404 in addition to the thin film cell 22. Any or all of the layers 404 can be film layers. The cell 22 and the layers 404 can be assembled to form the panel 402 in any desired manner, such as via lamination, edge sealing, mechanical connection, etc. In this configuration, the apparatus 20 is operative to consume materials, such as gases or water, that permeate the layers 404 of the panel 402.

As an alternative implementation, the apparatus 20 can be fit within an enclosure 12 by applying the thin film cell 400 to any surface or surfaces within the enclosure in order to position the cell 22 in a space in which gases are to be removed. For instance, in the VIP implementation described above, the thin film cell 400 could be secured to an inner surface of the gas impermeable membrane panels that surround the porous core material.

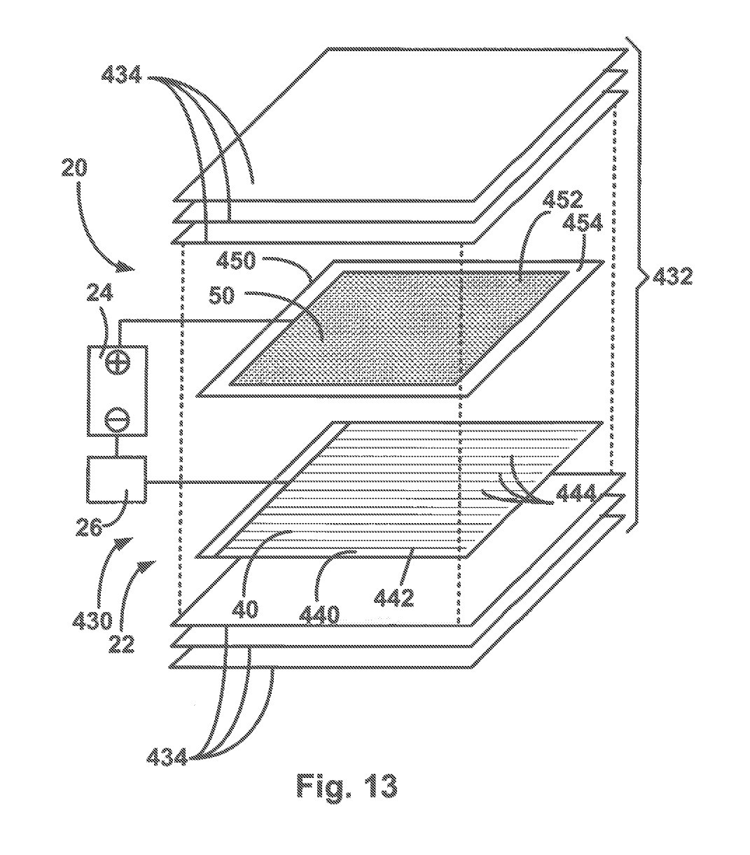

Another implementation in which the apparatus 20 or a portion thereof has a thin film construction is illustrated in FIG. 13. Referring to FIG. 13, the electrochemical cell 22 is formed as multiple layers, in which the cathode 40 is formed on one or more cathode layers 440 and the anode 50 is formed on one of more anode layers 450. The layers 440 and 450 together form the electrochemical cell 22 as a multilayer thin film cell 430. In the embodiment of FIG. 13, the multilayer thin film cell 430 includes one cathode layer 440 and one anode layer 450 that together define the electrochemical cell 22 of the apparatus 20. If multiple cathode and anode layers 440, 450 are implemented, they can be arranged in an alternating fashion. The number of anode layers 450 and cathode layers 440 do not necessarily have to be equal.

In this implementation, the anode layers 450 include a film substrate 452 upon which a layer of anode material 454 is disposed. The cathode layers 440 include a lithium ion conducting film 442 that supports one or more conductors 444, such as thin wires or traces, of a metal upon which metallic lithium can be deposited. Upon activation, lithium ions will be released from the anode film layer(s) 450 and metallic lithium will be deposited on the conductors 454 of the cathode film layer(s) 440. The metallic lithium can then react with any moisture present in the film. The power source 24 and actuator 26 may be located outside or away from the film and can be connected to the cathode 40 and anode 50 via electrical leads.

In the embodiment of the apparatus 20 depicted in FIG. 13, the electrochemical cell 22, having the multilayer thin film cell 430 construction, can be implemented in a variety of manners. For example, the apparatus 20 can be implemented in a multilayer film panel construction, as shown in FIG. 12. In this implementation, the multilayer thin film cell 430 forms one or more layers of a multilayer panel 432 that includes one or more layers 434 in addition to the cell. Any or all of the layers 434 can be film layers. The multilayer thin film cell 430 and the layers 434 can be assembled to form the panel 432 in any desired manner, such as via lamination, edge sealing, mechanical connection, etc. In this configuration, the apparatus 20 is operative to consume materials, such as gases or water, that permeate the layers 434 of the panel 432.

As an alternative implementation, instead of being implemented in a multilayer panel 432, the apparatus 20 can be fit within an enclosure 12 by applying the multilayer thin film cell 430 to any surface or surfaces within the enclosure in order to position the cell in a space in which gases are to be removed. In a further implementation, the apparatus 20 can be applied in a VIP vacuum insulating panel by applying the multilayer thin film cell 430 on an inner surface of the gas impermeable membrane panels that surround the porous core material.

Another implementation in which the apparatus 20 or a portion thereof has a thin film construction is illustrated in FIG. 14. Referring to FIG. 14, the electrochemical cell 22 is formed as multiple layers, in which the cathode 40 is formed on one or more cathode layers 540, the anode 50 is formed on one of more anode layers 550, and the electrolyte is formed as one or more electrolyte layers 560. The cathode layers 540, anode layers 550, and electrolyte layers 560 together form the electrochemical cell 22 as a multilayer thin film cell 530. In the embodiment of FIG. 14, the multilayer thin film cell 530 includes one each of the cathode layer 540, anode layer 450, and electrolyte layer 560 that together define the electrochemical cell 22 of the apparatus 20. If multiple cathode, anode, and electrolyte layers 540, 550, 560 are implemented, they can be arranged in an alternating fashion. The number of cathode layers 540, anode layers 550, and electrolyte layers 560 do not necessarily have to be equal.

In this implementation, the anode layers 550 can include a film substrate 552 upon which a layer of anode material 554 is disposed. The cathode layers 540 can include a lithium ion conducting film 542 that supports one or more conductors 544, such as thin wires or traces, of a metal upon which metallic lithium can be deposited. The SPE layer 560 can be a thin film constructed of a polymer material as described above, such as an SPE or a solid Li⁺ conductive material such as LIPON, LISICON, and thio-LISICON. In this configuration, the cathode conductors 544 could be disposed on the SPE layer 560 directly. The cathode and electrolyte could thus be formed as one layer of the multilayer structure.

Upon activation, lithium ions will be released from the anode film layer(s) 550 into the electrolyte layers 560, and metallic lithium will be deposited on the conductors 554 of the cathode film layer(s) 540 from the electrolyte layers. The metallic lithium can then react with any moisture or other gases to which it is exposed, such as those present in the film. The power source 24 and actuator 26 can be located outside or away from the film and can be connected to the cathode 40 and anode 50 via electrical leads.

In the embodiment of the apparatus 20 depicted in FIG. 14, the electrochemical cell 22, having the multilayer thin film cell 530 construction, can be implemented in a variety of manners. For example, the apparatus 20 can be implemented in a multilayer film panel construction, as shown in FIG. 12. In this implementation, the multilayer thin film cell 530 forms one or more layers of a multilayer panel 532 that includes one or more layers 534 in addition to the cell. Any or all of the layers 534 can be film layers. The multilayer thin film cell 530 and the layers 534 can be assembled to form the panel 532 in any desired manner, such as via lamination, edge sealing, mechanical connection, etc. In this configuration, the apparatus 20 is operative to consume materials, such as gases or water, that permeate the layers 534 of the panel 532.

As an alternative implementation, instead of being implemented in a multilayer panel 532, the apparatus 20 can be fit within an enclosure 12 by applying the multilayer thin film cell 530 to any surface or surfaces within the enclosure in order to position the cell in a space in which gases are to be removed. In a further implementation, the apparatus 20 can be applied in a VIP vacuum insulating panel by applying the multilayer thin film cell 430 on an inner surface of the gas impermeable membrane panels that surround the porous core material.

### Assembling the Electrochemical Cell

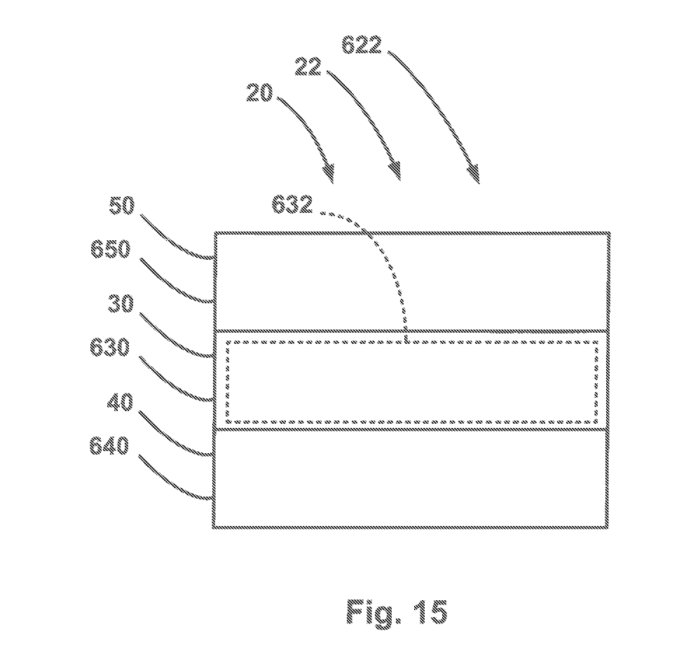

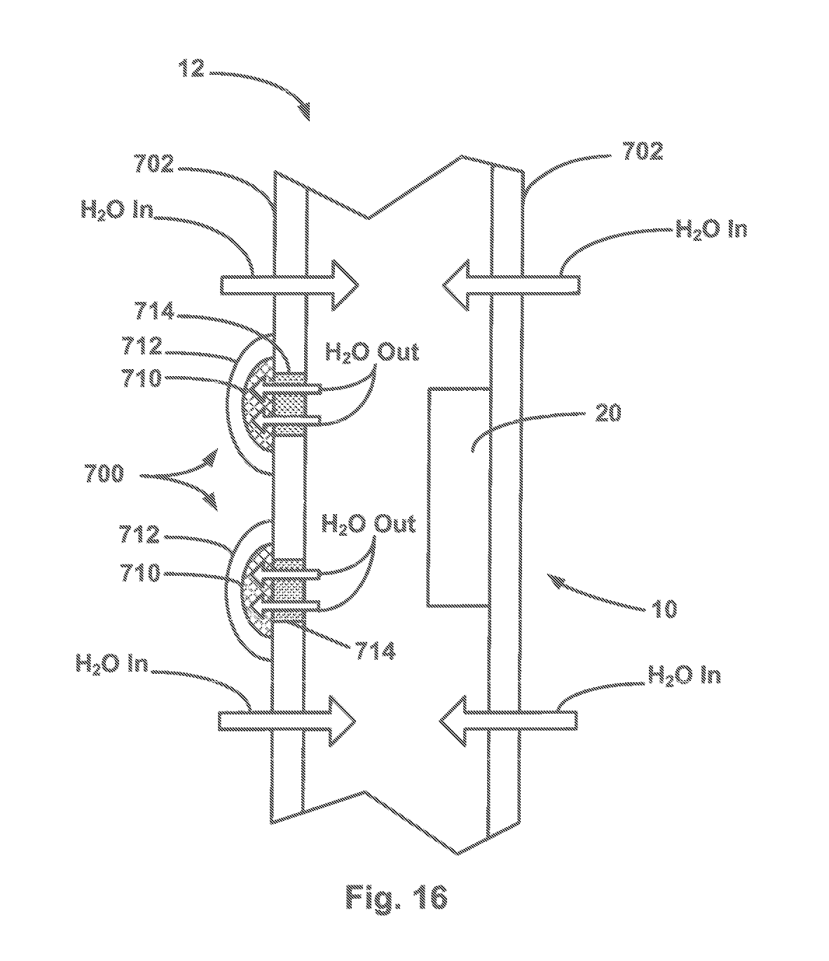

The electrochemical cell 22 of the apparatus 20 can be constructed or assembled in a variety of manners. For example, FIG. 15 illustrates a construction that can be used to produce an electrochemical cell, such as the cells 22 described herein with respect to FIGS. 2 and 10.

Referring to FIG. 15, the electrochemical cell 22 is formed as multiple layers, in which the cathode 40 is formed on one or more cathode layers 640, the anode 50 is formed on one of more anode layers 650, and the electrolyte 30 is formed as one or more electrolyte layers 630. The cathode layers 640, anode layers 650, and electrolyte layers 630 together form the electrochemical cell 22 as a multilayer cell 622. In the embodiment of FIG. 15, the multilayer cell 622 includes one each of the cathode layer 640, anode layer 650, and electrolyte layer 630 that together define the electrochemical cell 22 of the apparatus 20. If multiple cathode, anode, and electrolyte layers 630, 640, 650 are implemented, they can be arranged in an alternating fashion. The number of cathode layers 640, anode layers 650, and electrolyte layers 630 do not necessarily have to be equal.

In this configuration, the essentially flat layers are positioned on top of one another with the non-volatile electrolyte 630 positioned between the anode 650 and the cathode. This arrangement could involve an additional structural layer or layers (indicated generally in dashed lines at 632) between the two electrodes 640, 650 which serves to hold the electrolyte in place and thus prevent accidental contact between the two electrodes which might lead to shorting of the cell. The structural layer(s) 632 can, for example, have a mesh or cellular construction that maintains the space between the electrodes 640, 650 and within which the electrolyte 630 is contained.

The anode 650 can be composed of a solid layer of charge storage material supported on a solid current conductor. The current conductor can be prepared by, for example, physical vapor deposition (“PVD”), including thermal or electron beam evaporation, or chemical vapor deposition (“CVD”) including DC, sputtering from a solid or powder source or by pulsed laser deposition (“PLD”). The anode 650 can also be made based on the same techniques used for the fabrication of anodes for lithium ion batteries which involve a combination of micron size particles of the active material intermixed with particles of a conductivity enhancer such as high area carbon and also a binder to hold the mixture and give the electrode structural integrity.

The non-volatile electrolyte layer 630 can be a non-volatile lithium ion conducting polymer that can be prepared by such methods as spin casting or a doctor's blade. The non-volatile electrolyte layer 630 could also be a non-volatile lithium ion conducting ceramic that can be prepared by ceramic processing methods, such as those used in the case of LiPON and LISICON. The cathode 640 can he a porous film of a metal such as Ni or Co which can be coated with a layer of another material capable of forming alloys with the reactive material.

The electrochemical cell 622 can be assembled in a variety of manners. According to one assembly method, one of the electrodes, either the anode 650 or cathode. 640, can be placed flat on a surface followed by the electrolyte layer 630, and then the other flat electrode. A similar or identical protocol would be followed in the case of a non-volatile polymeric electrolyte. In this case, a flat polymeric mesh would be placed on the first electrode before laying down the other electrode. Once the layered structure is assembled, it can be used as-is, or rolled loosely to leave space between the rolled layers for enabling gas flow.

The construction of FIG. 15 is not limited to embodiments in which lithium is used as the reactive metal. The same or similar construction could be used, for example, with an electrochemical cell construction that uses magnesium or sodium as the reactive metal, both of which are mentioned and described above. In the case of magnesium, the cathode 640, anode 650, and electrolyte 630 would be constructed using the materials described above in regard to a magnesium construction.

In a construction in which the reactive metal is sodium, the electrolyte 630 is a non-volatile sodium ion conducting SPE, such as PEO or NASICON. The anode 640 includes a material capable of donating reactive sodium metal ions to the SPE. One example of a sodium ion conducting material is the fast sodium ion conductor Na₂M₂TeO₆ (where M=Ni, Co, Zn, Mg), which is described in a paper by Maria A. Evstigneeva, Chem. Mater., 2011, 23(5), pp 1174-1181, the disclosure of which is hereby incorporated by reference in its entirety. The cathode 640 can be made of materials upon which metallic sodium can be deposited or with which sodium can form alloys or intercalation compounds.

### Alternative Actuator Configurations

The apparatus 20 can implement actuator 26 configured to actuate the electrochemical cell 22 in manners additional to those described above. For instance, in addition to the pressure sensors activate the electrochemical cell 22 in response to pressure in the enclosure 12, the actuator 26 could comprise humidity or moisture sensors configured to activate the cell in response to water vapor in the enclosure.

As another alternative, the actuator 26 can comprise voltage sensors that can be used to activate the electrochemical cell 22 in response to a sensed voltage within the apparatus 20. In one example, these voltage sensors could be configured and arranged to activate the cell 22 in response to the metallic Li deposited on the cathode being exhausted due to reacting with atmospheric components in the enclosure 12. This condition can be monitored, for example, by using the voltage sensor to monitor the voltage across the cell, which will increase as the metallic Li is deposited on the cathode. In this implementation, a voltage drop across the cell after lithium had been deposited, to a threshold level indicative of metallic lithium in contact with the cathode being consumed, will serve as a trigger for activating the cell 22 to produce more metallic Li. The actuator can be configured to intermittently monitor the voltage across the cell to determine whether more metallic Li is required. In this manner, the apparatus 20 can be self-regulating.

### Hydrogen Consumption

Lithium does not readily react with hydrogen, so the apparatus 20 as described thus far is incapable of consuming this gas. Since pure or diatomic hydrogen (H₂) is not present in the atmosphere, the inability of the apparatus 20 to consume this gas may not be a concern. Hydrogen could, however, be produced as a by-product of the consumption reactions performed by the apparatus 20 as specified above. More specifically, hydrogen could be a by-product of a water consuming reaction performed by the apparatus 20 according to

2Li+2H₂O→2LiOH+H₂

Normally, this would not be of a great concern because the amount of hydrogen that could be produced is very small. Additionally, due to its extremely small molecular size, any hydrogen present in the enclosure 12 would simply leak out over time. There could, however, be applications in which the presence of any hydrogen is undesirable. In this instance, the apparatus 20 could be fit or paired with a commercially available hydrogen getter material, such as HiTop™ hydrogen getter products available commercially from Vacuum Energy, Inc. of Shaker Heights, Ohio.

### Water Vapor Removal

According to another aspect of the invention, the apparatus, i.e., the apparatus 20, can be implemented in a system that is specifically configured to consume gasses in an enclosure where moisture or water vapor accounts for a large portion of the gases that may enter the enclosure. This may be the case, for example, where the enclosure is formed by polymer films through which water vapor can permeate. As a specific example, these polymer films can serve as barriers in conventional VIPs, as it is common for these structures to rely on various types of polymers, in some cases coated with metallic layers. The polymer film barrier structures are intended to decrease the overall permeability of the barrier to water vapor, while keeping the heat conduction through the barrier to a minimum. Nevertheless, water vapor can permeate these barrier structures.

Referring to FIG. 16, the system 10 can include the apparatus 20 and an one or more additional structures or devices 700 for consuming water in a sealed enclosure 12. The enclosure 12 can, for example, be a VIP panel enclosure and therefore includes conventional polymer film barriers 702 that prevent the fast ingress of moisture into the enclosure. Water vapor can, over time, permeate the barriers 702 and enter into the enclosure 12, as indicated generally by the arrows labeled “H₂O In” in FIG. 16.

The water consuming structures 700 include VIP enclosure (see blue area in FIG. 1), incorporating sections which are devoid of the required components aimed at decreasing the water vapor permeability (unprotected areas, yellow sections) thereby allowing moisture to flow freely through it. The relative rates of water transport through the two sections are represented by the size of the arrows in that figure. A desiccant, such as CaO in the form of a compressed pellet shown by the grey area in FIG. 2, is then placed on top of the unprotected area of the barrier facing outside which is then trapped between an additional polymeric layer highly impermeable to the flow of moisture, shown in magenta in FIG. 2, bonded to the blue section of the barrier. In this fashion, water vapor permeating into the enclosure at a slow rate (narrow arrows) will permeate out of the enclosure in the unprotected areas (thick arrow) and be captured by the desiccant.

### Pressure Monitoring and Control

According to another aspect of the invention, the system 10 and the apparatus 20, i.e., the VOD device, can be configured to implement a method for monitoring, assessing, and reacting to the gas atmosphere within an enclosure 12, such as a VIP, an evacuated or pressure reduced enclosure, or an enclosure in which one or more gases in the enclosure are to be removed or otherwise controlled. The conditions that the apparatus 20 can be configured to monitor, assess, and react to include the pressure and composition of the gases in the enclosure, although neither of these would be measured directly. Instead, according to this method, the apparatus 20 is configured to monitor the time required for a reactive metal, such as metallic lithium, to react with the gases in the enclosure (except, of course, noble gases such as argon) to yield stable non-volatile solid materials.

According to the invention, the apparatus 20 described herein can be adapted, programmed, or otherwise controlled to form a highly controlled amount of metallic lithium in the manner(s) disclosed herein. The apparatus 20 can be further adapted, programmed, or otherwise controlled to measure precisely the amount of time it takes for that controlled amount of metallic lithium to react with the gases in the enclosure. To do this, the apparatus 20 is configured to electrodeposit a given amount of metallic lithium on the cathode 40, which is exposed to the gases in the enclosure. By applying current or voltage to the electrochemical cell in a highly precise and controlled manner and for a precise and controlled period of time, a precise amount of metallic lithium can be deposited on the cathode 40 Immediately after depositing the metallic lithium on the cathode 40, the voltage across the electrochemical cell of the apparatus 20 is monitored.

According to principles of thermodynamics, this open circuit potential provides a measure of the composition of both electrodes in intimate contact with the electrolyte. For example, should metallic lithium be formed at the cathode-electrolyte interface, the voltage of that electrode with respect to the anode 50 will be given by the difference between the thermodynamic redox potential of the Li⁺|Li redox couple in the specific electrolyte 30 used and the potential of the partially charged anode in that same electrolyte. Should gases present in the enclosure react with the metallic lithium leading eventually to its consumption, the open circuit potential of the apparatus 20 will decrease. According to the invention, this decrease in potential can be used as an indication of the presence of consumable gases in the enclosure.

The apparatus 20 is configured to monitor over time the potential across the electrochemical cell, and to identify the presence of non-noble gases in the enclosure 12 based on a drop in this potential. The identification can be as simple as providing an indication of a potential problem, such as leaks in the enclosure 12, inferred from the drop in voltage. The identification can, however, be more sophisticated, taking time into consideration. For example, some ingress of non-noble gases into the enclosure 12 is inevitable over time. Therefore, it can be expected that a apparatus 20 in a normally functioning enclosure with an intact seal will eventually produce an indication that the voltage across the apparatus has dropped due to consumption of the deposited metallic lithium over a prolonged period of time. Thus, it could be expected that the apparatus 20 may detect a voltage drop after some long period of time, over months or years, for example, or even up to five or ten years or longer, as another example.

This being the case, a detected voltage drop across the apparatus 20 after this prolonged period may not tell the whole story. The drop could be due to normal ingress into the enclosure 12 over the long time period or to a rapid ingress over a recent time period. Therefore, when the apparatus 20 detects a voltage drop indicative of an ingress of gases into the enclosure, it can respond by electrodepositing an additional amount of metallic lithium and monitoring the amount of time it takes for this additional lithium metal to be consumed. If the original voltage drop was due to normal ingress, then the re-deposited metallic lithium will last another long period of time and no alarm is necessary. If, however, the re-deposited lithium gets consumed quickly, then the resulting voltage drop can be considered indicative of a problem with the enclosure 12. Accordingly, the apparatus 20 can be self-regulating, determining when to replenish the supply of metallic lithium based on when it gets consumed, while monitoring this replenishment in relation to time in order to determine whether there may be a problem with the enclosure. As a further advantage, this process of depositing lithium and monitoring for replenishment can be used as a method for minimizing the amount of metallic lithium that is present at any given time without affecting the capacity of the apparatus 20 to consume the predetermined amount of gas.

While completely capable of operating autonomously and without requiring any input from outside, this monitoring capability and function of the apparatus 20 can advantageously be tapped to provide information to outside systems or users. In its simplest form, the monitoring function can be used to provide indicia on the unit itself, such as lights or displays, that indicate the conditions sensed by the apparatus 20. For instance, the indicia could be used to alert the user to the potential for a leak or to indicate the need to replace or repair the enclosure.

In a more sophisticated form, since it is simple to assign a unique identifier, such as a serial number, to each apparatus 20, that identifier can be used to tie the sensed or determined conditions with the specific apparatus that senses/determines the conditions. Connecting the apparatus 20 to a network, the information provided by the apparatus can be utilized by any device or system that has access to that network. For example, connected to a local building control network, the apparatus could be used by maintenance personnel to monitor where in the building insulation panels (VIPs) or windows utilizing the apparatus need attention. Connecting to the internet, this information can be accessed from virtually any location in the world.

As another example, where the enclosure is associated with an appliance, such as insulation (e.g., a VIP) in a refrigerator, oven, or hot water heater, that appliance can be connected to the internet, e.g., the internet of things, which allows the appliance to be monitored, e.g., via the cloud. This opens up a world of possibilities for using the information. For example, a homeowner could be alerted when his refrigerator's insulation is failing and could take corrective action. Otherwise, not realizing that there is a problem with the insulation, the refrigerator could run excessively for an extended period of time and waste a great deal of energy and money in doing so. In fact, administered correctly, a manufacturer could offer free or discounted repair or replacement of the appliance proactively when the problem is first detected.

### Pressure Monitoring and Control

According to another aspect of the invention, the system 10 and the apparatus 20 can be configured to implement a method for monitoring, assessing, and reacting with gases, including those in the atmosphere within an enclosure 12, such as a VIP, an evacuated or pressure reduced enclosure, or an enclosure in which one or more gases in the enclosure are to be removed or otherwise controlled. The conditions that the apparatus 20 can be configured to monitor, assess, and react to include the pressure and composition of the gases in the enclosure, although neither of these would be measured directly. Instead, according to this method, the apparatus 20 is configured to monitor the time required for a reactive metal, such as metallic lithium, to react with the gases in the enclosure (except, of course, noble gases such as argon) to yield stable non-volatile solid materials.

According to the invention, the apparatus 20 described herein can be adapted, programmed, or otherwise controlled to form a highly controlled amount of metallic lithium in the manner(s) disclosed herein. The apparatus 20 can be further adapted, programmed, or otherwise controlled to measure precisely the amount of time it takes for that controlled amount of metallic lithium to react with the gases in the enclosure. To do this, the apparatus 20 is configured to electrodeposit a given amount of metallic lithium on the cathode 40, which is exposed to the gases in the enclosure. By applying current or voltage to the apparatus 20 in a highly precise and controlled manner and for a precise and controlled period of time, a precise amount of metallic lithium can be deposited on the cathode 40. Immediately after depositing the metallic lithium on the cathode 40, the voltage across the electrochemical cell of the apparatus 20 is monitored.

According to principles of thermodynamics, this open circuit potential provides a measure of the composition of both electrodes in intimate contact with the electrolyte. For example, should metallic lithium be formed at the cathode-electrolyte interface, the voltage of that electrode with respect to the VOD anode will be given by the difference between the thermodynamic redox potential of the Li⁺|Li redox couple in the specific electrolyte used and the potential of the partially charged anode in that same electrolyte. Should gases present in the enclosure react with the metallic lithium leading eventually to its consumption, the open circuit potential of the apparatus 20 will decrease. According to the invention, this decrease in potential can be used as an indication of the presence of consumable gases in the enclosure.

The apparatus 20 is configured to monitor over time the potential across the apparatus 20, and to identify the presence of non-noble gases in the enclosure based on a drop in this potential. The identification can be as simple as providing an indication of a possible problem, such as leaks in the enclosure, strictly inferred from the drop in voltage. The identification can, however, be more sophisticated, taking time into consideration. For example, some ingress of non-noble gases into the enclosure is inevitable over time. Therefore, it can be expected that the apparatus 20 in a normally functioning enclosure with an intact seal will eventually produce an indication that the voltage across the apparatus 20 has dropped due to consumption of the deposited metallic lithium over a prolonged period of time resulting from reactions between the deposited metallic Li and gases within the enclosure. Thus, it could be expected that the VOD detect a voltage drop after some long period of time, over months or years, for example, up to five or ten years or longer.

This being the case, a detected voltage drop after this prolonged period may not tell the whole story. The drop could be due to normal ingress of gases over the long time period or to a rapid ingress over a recent time period. Therefore, when the apparatus 20 detects a voltage drop indicative of an ingress of gases into the enclosure, it can respond by electrodepositing a small amount of metallic lithium and monitoring the length of time it takes for this additional lithium metal to be consumed. If the original voltage drop was due to normal ingress, then the re-deposited metallic lithium will last another long period of time and no alarm is necessary. If, however, the newly deposited lithium gets consumed quickly, then the resulting voltage drop can be considered indicative of a problem with the enclosure. Accordingly, the apparatus 20 can be self-regulating, determining when to replenish the supply of metallic lithium based on when it gets consumed, while monitoring this replenishment in relation to time in order to determine whether there may be a problem with the enclosure. As a further advantage, this process of depositing lithium and monitoring for replenishment can be used as a method for minimizing the amount of metallic lithium that is present at any given time without affecting the capacity of the apparatus 20 to consume the predetermined amount of gas.

### Water Vapor Consumption

According to another aspect of the invention, the apparatus, i.e., the apparatus 20, can be implemented in a system that is specifically configured to consume gases in an enclosure where moisture or water vapor accounts for a large portion of the gases that may enter the enclosure. This may be the case, for example, where the enclosure is formed by polymer films through which water vapor can permeate. As a specific example, these polymer films can serve as barriers in conventional VIPs, as it is common for these structures to rely on various types of polymers, in some cases coated with metallic layers. The polymer film barrier structures are intended to decrease the overall permeability of the barrier to water vapor, while keeping the heat conduction through the barrier to a minimum. Nevertheless, water vapor can permeate these barrier structures.

Referring to FIG. 16, the system 10 can include the apparatus 20 and one or more additional structures or devices 700 for consuming water in a sealed enclosure 12. The enclosure 12 can be any enclosure for which water vapor ingress is undesirable. For example, the sealed enclosure 12 can be a VIP panel enclosure and therefore includes conventional polymer film barriers 702 that prevent the fast ingress of moisture into the enclosure. Water vapor can, over time, permeate the barriers 702 and enter into the enclosure 12, as indicated generally by the arrows labeled “H₂O In” in FIG. 16.

The water consuming structures 700 are positioned on an outer surface of the film barriers 702 and include areas 714 of the film barriers that are intentionally constructed to be permeable to water vapor. The water consuming structures 700 also include a layer of a material 712, such as a polymer film barrier material, that is highly resistant to water vapor penetration. which could be the same material as that of 702 The water consuming structures further include a desiccant 710, such as calcium oxide (CaO) that is disposed between the film barrier layer 712 and the film barrier 702 and is exposed to the permeable areas 714 of the enclosure 12. The desiccant 710 can, for example, be in the form of a compressed pellet. In operation, the film barriers 702 and 712 allow water vapor penetration into the sealed enclosure 12, indicated generally by the arrows labeled “H₂O In,” at a very low rate. The permeable areas 714 of the enclosure 702 allow for water vapor to escape the sealed enclosure 12, as indicated generally by the arrows labeled “H₂O Out,” at a comparatively high rate. As a result, water vapor that penetrates into the sealed enclosure 12 through the film barriers 702 at the slow rate is permitted to pass quickly, i.e., at a comparatively high rate, out of the sealed enclosure 12 through the permeable areas 714, where it can be absorbed quickly by the desiccant 710. The film barrier layer 714 of the water consuming structures 700 helps prevent water vapor from penetrating directly to the desiccant 710 and imparts the overall envelope better mechanical integrity.

As a result, the combination of the gas consuming apparatus 20 and the water consuming structures 700 can improve the getter performance of the system 10 as a whole. The water consuming structures can serve as a getter for water vapor, which remove that duty from the gas consuming apparatus 20, which can be left to act as a getter for other non-noble gasses. While the apparatus 20 still can serve as a water vapor getter, the desiccant 710 of the water consuming structures 700 can do the bulk of that work. Additionally, the configuration of the water consuming structures 700 could be designed such that the desiccant 710, when saturated or spent, can be removed and replaced with fresh desiccant material. Further, the water consuming structures 700 could be designed as a unit that can be removed and replaced in total, e.g., peel and stick.

From the above description of the invention, those skilled in the art will perceive improvements, changes and modifications. These and other such improvements, changes and modifications within the skill of the art are intended to be covered by the appended claims.

1-38. (canceled)

39. An apparatus for consuming gases, comprising:
an electrochemical cell comprising a cathode, an anode, and an electrolyte;
a power source for supplying power for operating the electrochemical cell;
a controller for controlling the supply of power to the electrochemical cell; and
at least one sensor for sensing conditions associated with the apparatus,
wherein the controller comprises electronics and/or circuitry that is adapted to sense, via the at least one sensor, conditions related to the electrochemical cell and to operate the electrochemical cell in response to the sensed conditions, and
wherein the cell is operable to produce an electrochemical reaction that forms on the cathode a reactive material comprising at least one of a metal, an alloy, and an intercalation compound, and wherein the cell is constructed so that the reactive material formed on the cathode is exposed to the gases that are to be consumed.

40. The apparatus recited in claim 39, wherein the at least one sensor comprises a voltage sensor for measuring voltage across the cell, and the controller is configured to control operation of the cell in response to the measured voltage.

41. The apparatus recited in claim 40, wherein controller is configured to associate a drop in the voltage measured across the cell with the reactive material formed on the cathode being consumed due to reacting with gases.

42. The apparatus recited in claim 41, wherein controller is operative to measure the time required to consume a precise amount of the reactive material and to associate that time with an amount of consumed gas.

43. The apparatus recited in claim 40, wherein controller is configured to associate a drop in the voltage measured across the cell with the presence of consumable gases.

44. The apparatus recited in claim 40, wherein controller is configured to associate a drop in the voltage measured across the cell with an ingress of gases into an enclosure in which the apparatus is located.

45. The apparatus recited in claim 40, wherein controller is configured to respond to a drop in the voltage measured across the cell by operating the cell to form additional reactive material on the cathode.

46. The apparatus recited in claim 39, wherein the apparatus is connectable to a network and operable to provide data related to the consumption of the reactive material via the network.

47. The apparatus recited in claim 39, wherein the cell when operated causes lithium ions to be released from the anode into the electrolyte, and metallic lithium from the electrolyte to be deposited on or alloy with the conductors of the cathode, the metallic lithium reacting with and consuming the gases.

48. The apparatus recited in claim 39, wherein the cell has a multilayer thin-film configuration in which the cathode comprises at least one cathode layer, the anode comprises at least one anode layer, and the electrolyte comprises at least one electrolyte layer.

49. The apparatus recited in claim 48, wherein:
each of the at least one anode layer comprises a substrate upon which a layer of anode material is disposed;
each of the at least one cathode layer comprises a lithium ion conducting film that supports one or more conductors formed of a material with which lithium can form alloys, upon which metallic lithium can be deposited, or with which lithium can form an intercalation compound; and
each of the at least one electrolyte layer comprises a solid polymer electrolyte film.

50. The apparatus recited in claim 48, wherein each of the at least one electrolyte layer comprises a thin film ceramic type ion conducting electrolyte such as LiPON, LISICON and thio-LISICON.

51. The apparatus recited in claim 48, wherein the at least one cathode layer and the at least one electrolyte layer are formed as a unitary sheet in which the electrolyte layer comprises a lithium ion conducting film and the cathode comprises one or more conductors of a metal upon which metallic lithium can be deposited or with which lithium can form alloys, such as thin wires or traces, that are deposited on the lithium ion conducting film.

52. The apparatus recited in claim 48, wherein the at least one anode layer, at least one cathode layer, and at least one electrolyte layer are combined to form a multilayer panel through at least one of lamination, edge sealing, and mechanical connections.

53. The apparatus recited in claim 39, wherein the apparatus is configured for installation in an insulated window to expose the reactive material formed on the cathode to the space between panes of the window, so that the reactive material can react with non-noble gases in the space between the panes.

54. The apparatus recited in claim 39, further comprising at least one of RF transducers, tags, interrogators, transmitters, and receivers configured for remote communication with the apparatus.

55. The apparatus recited in claim 39, further comprising a non-electronic manual or mechanical actuator for actuating the controller.

56. The apparatus recited in claim 39, wherein the reactive material is lithium, and wherein:
the anode is constructed of a lithium-ion containing material;
the electrolyte comprises a non-volatile lithium ion conducting material; and
the cathode is constructed of a material with which lithium can form alloys, upon which metallic lithium can be deposited, or with which lithium can form an intercalation compound.

57. The apparatus recited in claim 56, wherein the electrolyte comprises a lithium containing salt selected from the following group:
lithium hexafluorophosphate (LiPF₆)
lithium bis(trifluoromethane)sulfonamide (CF₃SO₂NLiSO₂CF₃)
lithium trifluoromethanesulfonate (CF₃SO₃Li)
lithium tetrafluoroborate (LiBF₄)
lithium perchlorate (LiClO₄)
lithium bromide (LiBr).

58. The apparatus recited in claim 56, wherein the electrolyte comprises a solid polymer electrolyte.
